(19) United States
(12) Patent Application Publication
(10) Pub. No.: US 2025/0336861 A1
(43) Pub. Date: Oct. 30, 2025

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventors: Jung Shik JANG, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 18/930,452

(22) Filed: Oct. 29, 2024

(30) Foreign Application Priority Data
Apr. 26, 2024 (KR) 10-2024-0055943

(51) Int. Cl. H01L 23/00; H01L 25/18; H10B 43/20; H10B 43/30

(52) U.S. Cl. CPC H01L 24/08; H01L 25/18; H10B 43/20; H10B 43/30; H01L 2224/08148; H01L 2225/06513; H01L 2924/1438

(57) ABSTRACT

Provided herein is a semiconductor device and a method of manufacturing the semiconductor device. The semiconductor device includes a source layer spaced apart from a substrate and disposed in a cell area of the substrate, a source cutting insulating layer spaced apart from the substrate and disposed in a contact area of the substrate, a plurality of discharge contacts penetrating the source cutting insulating layer and extending downwards, and a plurality of contact pads penetrating the source cutting insulating layer and contacting an upper portion of each of the plurality of discharge contacts, respectively. Each of the plurality of contact pads may include an extender extending in a horizontal direction.

### CROSS-REFERENCE TO RELATED APPLICATION

The present application claims priority under 35 U.S.C. § 119(a) to Korean patent application number 10-2024-0055943 filed on Apr. 26, 2024, in the Korean Intellectual Property Office, the entire contents of which application is incorporated herein by reference.

### BACKGROUND

### 1. Technical Field

Various embodiments of the present disclosure generally relate to an electronic device, and more particularly to a semiconductor device and a method of manufacturing the semiconductor device.

### 2. Related Art

A nonvolatile memory device is a memory device in which stored data is retained even when power supply is interrupted. Recently, as improvement in the integration degree of a two-dimensional (2D) nonvolatile memory device in which memory cells are formed in a single layer on a substrate has reached its limit, a three-dimensional (3D) nonvolatile memory device in which memory cells are vertically stacked on the substrate is being proposed.

The 3D nonvolatile memory device includes alternately stacked interlayer insulating layers and gate electrodes, and channel layers penetrating them, with the memory cells stacked along the channel layers. To improve the operational reliability of the nonvolatile memory device having such a 3D structure, various structures and manufacturing methods are being developed.

### SUMMARY

An embodiment of the present disclosure may provide for a semiconductor device. The semiconductor device may include a source layer spaced apart from a substrate and disposed in a cell area of the substrate, a source cutting insulating layer insulating layer spaced apart from the substrate and disposed in a contact area of the substrate, a plurality of discharge contacts penetrating the source cutting insulating layer and extending downwards, and a plurality of contact pads penetrating the source cutting insulating layer and contacting upper portions of the plurality of discharge contacts, respectively, wherein each of the plurality of contact pads may include an extender extending in a horizontal direction.

An embodiment of the present disclosure may provide for a semiconductor device. The semiconductor device may include a source layer spaced apart from a substrate and disposed in a cell area of the substrate, a source cutting insulating layer spaced apart from the substrate and disposed in a contact area of the substrate, a cell stacked layer including interlayer insulating layers and conductive patterns that are alternately stacked on the source layer, a dummy stacked body including dummy interlayer insulating layers and sacrificial insulating layers that are alternately stacked on the source cutting insulating layer, a channel structure penetrating the cell stacked layer and extending into the source layer, a cell plug pad disposed between the source layer and the channel structure, a plurality of discharge contacts penetrating the source cutting insulating layer and extending downwards, and a plurality of contact pads penetrating the source cutting insulating layer and contacting upper portions of the plurality of discharge contacts, respectively, wherein each of the plurality of contact pads may include an extender extending in a horizontal direction.

An embodiment of the present disclosure may provide for a method of manufacturing a semiconductor device. The method may include forming a source layer on a memory cell area of a substrate, and forming a source cutting insulating layer on a contact area of the substrate, forming openings that pass through the source cutting insulating layer, and forming discharge contacts by filling the openings with a conductive material, forming recess areas each including extenders that overlap the discharge contacts, and forming contact pads within the recess areas.

An embodiment of the present disclosure may provide for a method of manufacturing a semiconductor device. The method may include forming a source layer on a memory cell area of a substrate, and forming a source cutting insulating layer on a contact area of the substrate, forming openings that pass through the source cutting insulating layer, and forming discharge contacts by filling the openings with a conductive material, forming recess areas each including extenders that overlap the discharge contacts, forming a plurality of holes by etching the source layer to a certain depth, and forming contact pads in the recess areas, and forming cell plug pads in the plurality of holes.

### BRIEF DESCRIPTION OF THE DRAWINGS

FIG. 1 is a block diagram schematically illustrating a semiconductor device according to an embodiment of the present disclosure.

FIG. 2 is a sectional view illustrating a semiconductor device according to embodiments of the present disclosure.

FIG. 3 is a perspective view for explaining a connection relationship between a contact pad, a discharge contact, and a lower line of FIG. 2.

FIGS. 4A, 4B, 4C, 4D, 4E, 4F, 4G, 4H, 41, 4J, 4K, and 4L are sectional views and plan views for explaining a method of manufacturing a semiconductor device according to an embodiment of the present disclosure.

FIG. 5 is a sectional view illustrating a semiconductor device according to various embodiments of the present disclosure.

FIGS. 6A, 6B, 6C, 6D, 6E, 6F, 6G, 6H, 6I, and 6J are sectional views for explaining a method of manufacturing a semiconductor device according to an embodiment of the present disclosure.

FIG. 7 is a block diagram illustrating the configuration of a memory system according to an embodiment of the present disclosure.

FIG. 8 is a block diagram illustrating the configuration of a memory system according to an embodiment of the present disclosure.

FIG. 9 is a block diagram illustrating the configuration of a computing system according to an embodiment of the present disclosure.

FIG. 10 is a block diagram illustrating a computing system according to an embodiment of the present disclosure.

### DETAILED DESCRIPTION

Specific structural or functional descriptions in the embodiments of the present disclosure introduced in this specification or application are only for description of the embodiments of the present disclosure. The descriptions should not be construed as being limited to the embodiments described in the specification or application.

Hereinafter, embodiments of the present disclosure will be described in detail with reference to the accompanying drawings such that those skilled in the art can practice the present disclosure.

Various embodiments of the present disclosure are directed to a semiconductor device and a method of manufacturing the semiconductor device, in which pads connected to contact plugs, respectively, are extended to have different lengths in a horizontal direction and are connected to lower contacts through extenders.

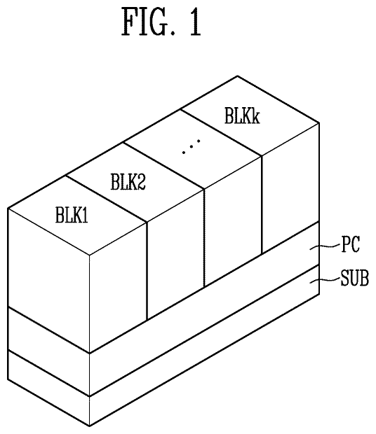

FIG. 1 is a block diagram schematically illustrating a semiconductor device according to an embodiment of the present disclosure.

Referring to FIG. 1, the semiconductor device may include a peripheral circuit structure PC disposed on a substrate SUB and memory blocks BLK1 to BLKk (k is a natural number of 2 or more). The memory blocks BLK1 to BLKk may overlap the peripheral circuit structure PC.

The substrate SUB may be a single crystal semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth method.

The peripheral circuit structure PC may include a row decoder, a column decoder, a page buffer, a control circuit, etc., which constitute a circuit for controlling the operation of the memory blocks BLK1 to BLKk. For example, the peripheral circuit structure PC may include an NMOS transistor, a PMOS transistor, a resistor, and a capacitor that are electrically connected to the memory blocks BLK1 to BLKk. The peripheral circuit structure PC may be disposed between the substrate SUB and the memory blocks BLK1 to BLKk. However, the present disclosure does not exclude an embodiment in which the peripheral circuit structure PC extends to another area of the substrate SUB that does not overlap the memory blocks BLK1 to BLKk.

The memory blocks BLK1 to BLKk each may include impurity doping areas, bit lines, cell strings electrically connected to the impurity doping areas and the bit lines, word lines electrically connected to the cell strings, and select lines electrically connected to the cell strings. Each of the cell strings may include memory cells and select transistors connected in series by a channel structure. Each of the select lines may be used as a gate electrode of the corresponding select transistor, and each of the word lines may be used as a gate electrode of the corresponding memory cell.

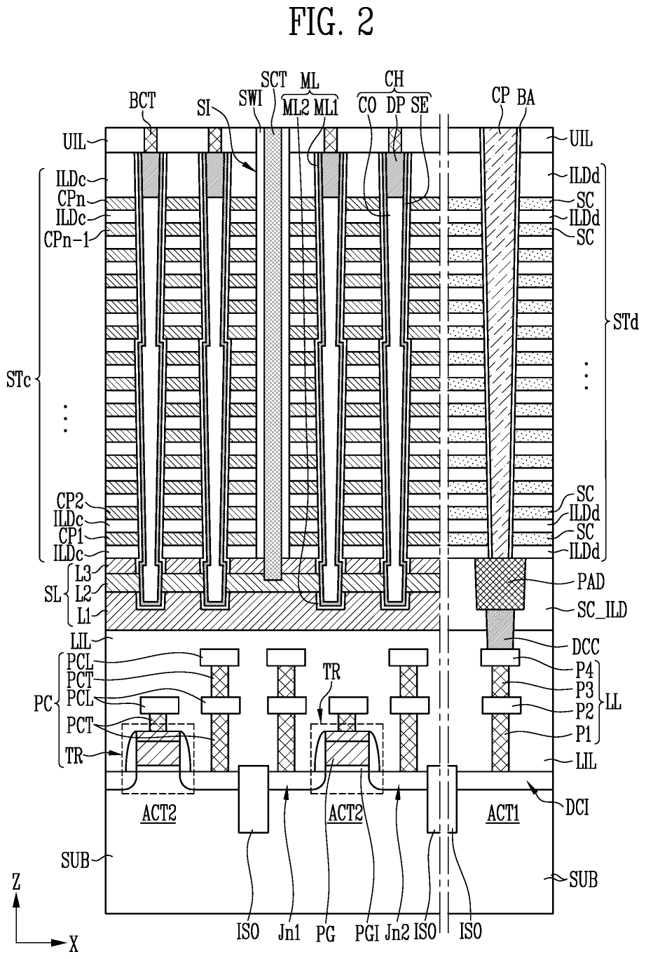

FIG. 2 is a sectional view illustrating a semiconductor device according to various embodiments of the present disclosure.

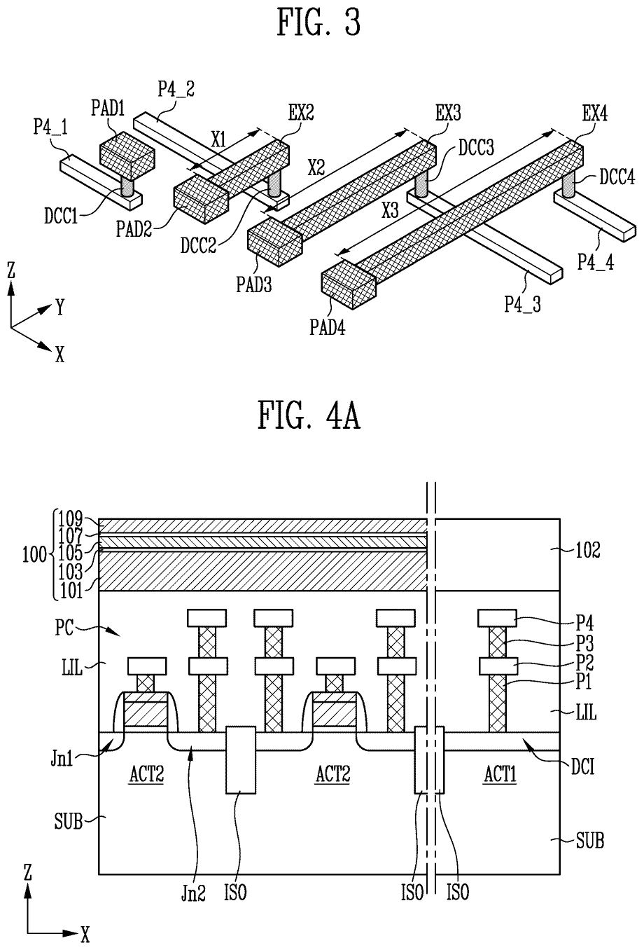

Referring to FIG. 2, the semiconductor device may include a source layer SL disposed on the substrate SUB, and a cell stacked layer STc disposed on the source layer SL. The semiconductor device may include a source cutting insulating layer SC_ILD disposed on the substrate SUB, a dummy stacked body STd disposed on the source cutting insulating layer SC_ILD, a contact plug CP extending in the dummy stacked body STd in a vertical direction Z to contact an upper surface of the contact pad PAD, and a discharge contact DCC contacting a lower surface of the contact pad PAD and extending downwards. The source layer SL and the source cutting insulating layer SC_ILD may be disposed adjacent to each other on the same level in a first horizontal direction X. In an embodiment, the downward direction may be opposite the vertical direction Z. In an embodiment, the Z direction may be orthogonal to the X Y plane as shown in FIG. 3. For example, the discharge contact DCC may extend downwards towards the substrate SUB as shown in FIG. 2. In an embodiment the contact pad PAD may penetrate the source cutting insulating layer SC_ILD and contact the upper portion of the discharge contact DCC as shown in FIGS. 2 and 3.

An area of the substrate SUB overlapping the source layer SL and the cell stacked layer STc may be defined as a cell area. An area of the substrate SUB overlapping the source cutting insulating layer SC_ILD, the dummy stacked body STd, and the contact plug CP may be defined as a contact area.

The substrate SUB may be formed of the same material as the substrate SUB described above with reference to FIG. 1. Conductive dopants defining a well area may be implanted into the substrate SUB. The conductive dopant defining the well area may be an n-type or p-type impurity. The well area of the substrate SUB may be divided into active areas ACT1 and ACT2 partitioned by device isolation layers (or isolation layers) ISO. The device isolation layers ISO may include an insulating material embedded in the substrate SUB. The active areas ACT1 and ACT2 may include a first active area ACT1 overlapping the discharge contact DCC, and one or more second active areas ACT2 overlapping the cell stacked layer STc.

The source layer SL and the source cutting insulating layer SC_ILD may be arranged to be spaced apart from the substrate SUB by the peripheral circuit structure PC and a lower insulating structure LIL. The source layer SL and the source cutting insulating layer SC_ILD may be disposed adjacent to each other at the same height. For example, the source layer SL may be disposed on the cell area of the substrate SUB, and the source cutting insulating layer SC_ILD may be disposed on the contact area of the substrate SUB.

The peripheral circuit structure PC may include a transistor TR described with reference to FIG. 1. The transistor TR may include a peripheral-gate insulating layer PGI disposed on the second active area ACT2, a peripheral-gate electrode PG disposed on the peripheral-gate insulating layer PGI, and first and second junctions Jn1 and Jn2 disposed in the second active area ACT2 on opposite sides of the peripheral-gate electrode PG. The first and second junctions Jn1 and Jn2 may be areas defined by implanting the n-type or p-type impurity into the second active area ACT2. One may be used as a source junction, while the other may be used as a drain junction.

The peripheral circuit structure PC may include connecting lines PCL and peripheral-contact plugs PCT connected to the transistor TR. The peripheral circuit structure PC may include a resistor, a capacitor, etc. as described with reference to FIG. 1, in addition to the transistor TR and the connecting lines PCL and the peripheral-contact plugs PCT connected thereto.

The conductive impurity may be implanted into the first active area ACT1. In an embodiment, a discharge impurity area DCI may be defined in the first active area ACT1. The discharge impurity area DCI may include conductive impurities forming a PN diode.

The above-described peripheral circuit structure PC may be covered with a lower insulating structure LIL disposed between the source layer SL and the source cutting insulating layer SC_ILD and the substrate SUB. The lower insulating structure LIL may be extended to cover the discharge impurity area DCI. The lower insulating structure LIL may include insulating layers stacked in multiple layers.

The source layer SL may be disposed on the lower insulating structure LIL. The source layer SL may include two or more semiconductor layers L1, L2, and L3. For example, the source layer SL may include first to third semiconductor layers L1 to L3 that are sequentially stacked on the lower insulating structure LIL. The first and second semiconductor layers L1 and L2 each may be a doped semiconductor layer containing the source dopant. In an embodiment, each of the first and second semiconductor layers L1 and L2 may include a doped silicon layer containing the n type impurity. The third semiconductor layer L3 may be omitted in some cases. The third semiconductor layer L3 may include at least one of an n type doped silicon layer and an undoped silicon layer.

For example, the source cutting insulating layer SC_ILD may be penetrated by the contact pad PAD and the discharge contact DCC. Although one contact pad PAD and one discharge contact DCC are illustrated in the drawing, each of the contact pad PAD and the discharge contact DCC may be arranged to include multiple ones.

The discharge contact DCC may be connected to the lower line LL penetrating the lower insulating structure LIL to contact the discharge impurity area DCI of the substrate SUB. The lower line LL may include a plurality of lines P4 and P2 and a plurality of contacts P3 and P1.

The dummy stacked body STd may overlap the source cutting insulating layer SC_ILD and the contact pad PAD. The dummy stacked body STd may extend to cover the source cutting insulating layer SC_ILD and the contact pad PAD. The dummy stacked body may include dummy interlayer insulating layers ILDd and sacrificial insulating layers SC that are alternately stacked on the source cutting insulating layer SC_ILD and the contact pad PAD. The contact plug CP may penetrate the dummy stacked body STd in the vertical direction Z to be connected to the contact pad PAD, and a barrier layer BA may be formed on the sidewall of the contact plug CP.

The cell stacked layer STc may include cell interlayer insulating layers ILDc and conductive patterns CP1 to CPn (n is a natural number of 2 or more) that are alternately stacked on the source layer SL. The cell stacked layer STc may be arranged not to overlap the source cutting insulating layer SC_ILD and the contact pad PAD. The cell stacked layer STc may be disposed on the same level as the dummy stacked body STd. The cell interlayer insulating layers ILDc may be disposed on the same levels as the dummy interlayer insulating layers ILDd, and the conductive patterns CP1 to CPn may be disposed on the same levels as the sacrificial insulating layers SC.

The cell interlayer insulating layers ILDc and the dummy interlayer insulating layers ILDd may be formed of the same material, and formed through the same process. The sacrificial insulating layers SC may be formed of a material having an etch rate different from that of the cell interlayer insulating layers ILDc and the dummy interlayer insulating layers ILDd. For example, the cell interlayer insulating layers ILDc and the dummy interlayer insulating layers ILDd may include silicon oxide, and the sacrificial insulating layers SC may include silicon nitride.

Each of the conductive patterns CP1 to CPn may include various conductive materials such as a doped silicon layer, a metal layer, a metal silicide layer, and a barrier layer, and may include two or more types of conductive materials. For example, each of the conductive patterns CP1 to CPn may include tungsten and a titanium nitride layer (TiN) surrounding the surface of tungsten. Tungsten is a low-resistance metal, and may lower the resistance of the conductive patterns CP1 to CPn. The titanium nitride layer TiN is a barrier layer, and may prevent or mitigate direct contact between tungsten and the cell interlayer insulating layers ILDc.

The conductive patterns CP1 to CPn may be used as the gate electrodes of the cell string. The gate electrodes of the cell string may include source select lines, word lines, and drain select lines. The source select lines may be used as the gate electrodes of the source select transistors, the drain select lines may be used as the gate electrodes of the drain select transistors, and the word lines may be used as the gate electrodes of the memory cells.

The cell stacked layer STc may enclose the channel structure CH. That is, the channel structure CH may penetrate a portion of the cell stacked layer STc and the source layer SL. The channel structure CH may include a channel semiconductor layer. The channel semiconductor layer SE may include a silicon layer. The central area of the channel semiconductor layer SE may be filled with the core insulating layer CO. The core insulating layer CO may be formed to have a height lower than that of the channel semiconductor layer SE. A top central area of the channel semiconductor layer SE extending further upwards than the core insulating layer CO may be filled with a doped semiconductor pattern DP disposed on the core insulating layer CO. The doped semiconductor pattern DP may include the n type doped silicon layer. The channel semiconductor layer SE of the channel structure CH may be used as the channel area of the cell string, and the doped semiconductor pattern DP of the channel structure CH may be used as the drain junction of the cell string. The sidewall of the channel structure CH may be enclosed with a memory layer ML.

The channel structure CH may penetrate the cell stacked layer STc, and extend into the source layer SL. The sidewall of the channel structure CH overlapping the source layer SL may directly contact the source layer SL. In an embodiment, the second semiconductor layer L2 of the source layer SL may directly contact the sidewall of the channel semiconductor layer SE overlapping the second semiconductor layer L2. In this case, the memory layer ML may be separated into a first memory pattern ML1 and a second memory pattern ML2 by the second semiconductor layer L2. The first memory pattern ML1 may be disposed between the channel structure CH and the cell stacked layer STc, and extend between the channel structure CH and the third semiconductor layer L3. The second memory pattern ML2 may be disposed between the channel structure CH and the first semiconductor layer L1.

A portion of the channel structure CH extending into the source layer SL may be defined as a lower channel structure, and a portion of the channel structure CH penetrating the cell stacked layer STc may be defined as an upper channel structure. An uppermost portion of the lower channel structure and a lowermost surface of the upper channel structure may contact each other, and the uppermost surface critical dimension of the lower channel structure may be greater than the lowermost surface critical dimension of the upper channel structure.

The slit SI may be filled with a source contact structure SCT. The source contact structure SCT may be spaced apart from the cell stacked layer STc by a sidewall insulating layer SWI formed on the sidewall of the slit SI. The sidewall insulating layer SWI may be penetrated by the source contact structure SCT. The source contact structure SCT may extend to contact the source layer SL. The source contact structure SCT may include a single conductive material or two or more types of conductive materials. The conductive material for the source contact structure SCT may include a doped silicon layer, a metal layer, a metal silicide layer, a barrier layer, etc. For example, the source contact structure SCT may include a doped silicon layer contacting the source layer SL and a metal layer disposed on the doped silicon layer.

An upper insulating structure UIL may include a single insulating layer or two or more insulating layers. For example, the upper insulating structure UIL may include an oxide layer. The upper insulating structure UIL may be penetrated by a bit line contact plug BCT. The bit line contact plug BCT may be connected to the doped semiconductor pattern DP of the channel structure CH.

FIG. 3 is a perspective view for explaining a connection relationship between a contact pad, a discharge contact, and a lower line of FIG. 2.

Referring to FIG. 3, a plurality of contact pads PAD1, PAD2, PAD3, and PAD4 may be arranged side by side in a first horizontal direction X. Further, the plurality of contact pads PAD2, PAD3, and PAD4 may include extenders EX2, EX3, and EX4 extending in a second horizontal direction Y. The first horizontal direction X and the second horizontal direction Y may be horizontal directions that are orthogonal to each other. For example, the contact pad PAD2 includes the extender EX2 extending in the second horizontal direction Y, the contact pad PAD3 includes the extender EX3 extending in the second horizontal direction Y, and the contact pad PAD4 includes the extender EX4 extending in the second horizontal direction Y. The extenders EX2, EX3, and EX4 of the plurality of contact pads PAD2, PAD3, and PAD4 may extend to different lengths. For example, the extender EX2 of the contact pad PAD2 may extend by a first length X1, the extender EX3 of the contact pad PAD3 may extend by a second length X2 that is longer than the first length X1, and the extender EX3 of the contact pad PAD3 may extend by a third length X3 that is longer than the second length X2.

A plurality of discharge contacts DCC1, DCC2, DCC3, and DCC4 may correspond to the plurality of contact pads PAD1, PAD2, PAD3, and PAD4, respectively, and the plurality of discharge contacts DCC1, DCC2, DCC3, and DCC4 may be electrically connected to the plurality of contact pads PAD1, PAD2, PAD3, and PAD4, respectively.

For example, the discharge contact DCC1 may be electrically and physically connected to a lower surface of the contact pad PAD1, the discharge contact DCC2 may be electrically and physically connected to an end of the extender EX2 of the contact pad PAD2, the discharge contact DCC3 may be electrically and physically connected to an end of the extender EX3 of the contact pad PAD3, and the discharge contact DCC4 may be electrically and physically connected to an end of the extender EX4 of the contact pad PAD4. Thus, the plurality of discharge contacts DCC1, DCC2, DCC3, and DCC4 might not be arranged side by side in the first horizontal direction X, but may be arranged diagonally between the first horizontal direction X and the second horizontal direction Y.

A plurality of lower lines P4_1, P4_2, P4_3, and P4_4 may correspond to the plurality of discharge contacts DCC1, DCC2, DCC3, and DCC4, respectively, and the plurality of lower lines P4_1, P4_2, P4_3, and P4_4 may be electrically connected to the plurality of discharge contacts DCC1, DCC2, DCC3, and DCC4, respectively. The plurality of lower lines P4_1, P4_2, P4_3, and P4_4 may be arranged to be parallel to each other. Further, the plurality of lower lines P4_1, P4_2, P4_3, and P4_4 may extend in the first horizontal direction X, and the plurality of lower lines P4_1, P4_2, P4_3, and P4_4 may extend in both directions along the first horizontal direction X. For instance, the lower lines P4_1 and P4_2 may extend in one direction along the first horizontal direction, while the lower lines P4_3 and P4_4 may extend in an opposite direction along the first horizontal direction. Although not shown in the drawing, some of the plurality of lower lines P4_1, P4_2, P4_3, and P4_4 may extend in the second horizontal direction Y.

As described above, according to an embodiment of the present disclosure, because the plurality of contact pads PAD1, PAD2, PAD3, and PAD4 are connected to the plurality of discharge contacts DCC1, DCC2, DCC3, and DCC4 through the extenders, the plurality of discharge contacts DCC1, DCC2, DCC3, and DCC4 are not arranged to overlap each other in the first horizontal direction X and the second horizontal direction Y. Thus, in an embodiment, the plurality of lower lines P4_1, P4_2, P4_3, and P4_4 connected to the plurality of discharge contacts DCC1, DCC2, DCC3, and DCC4 may extend in different directions, thereby facilitating line design.

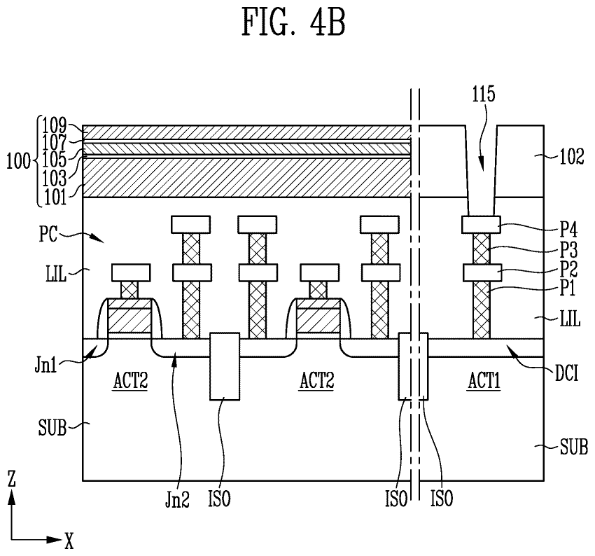

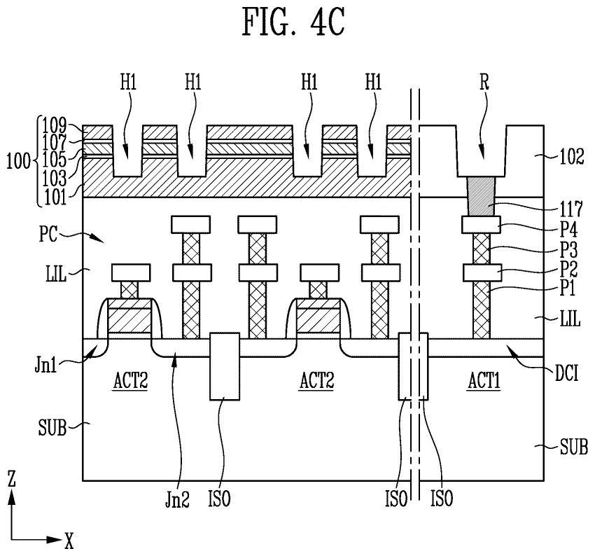

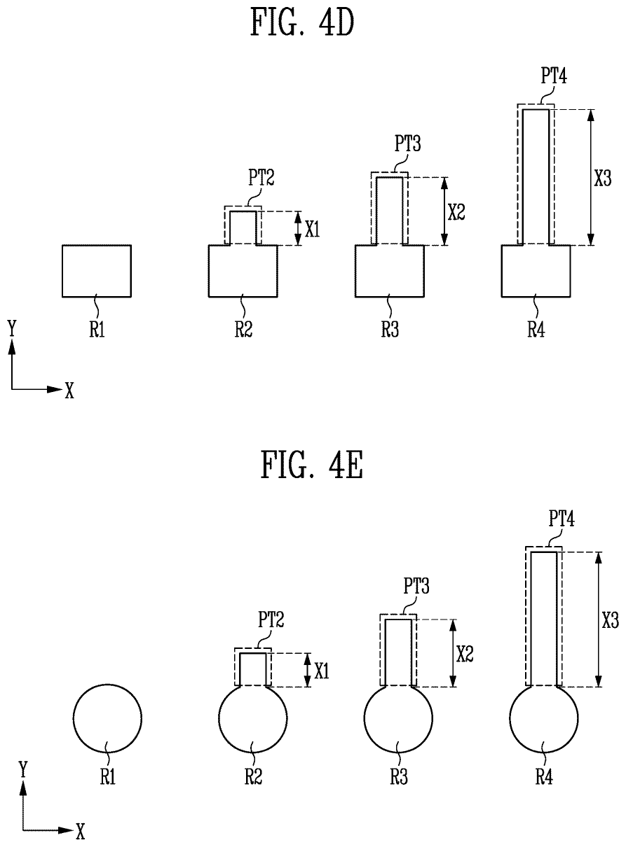

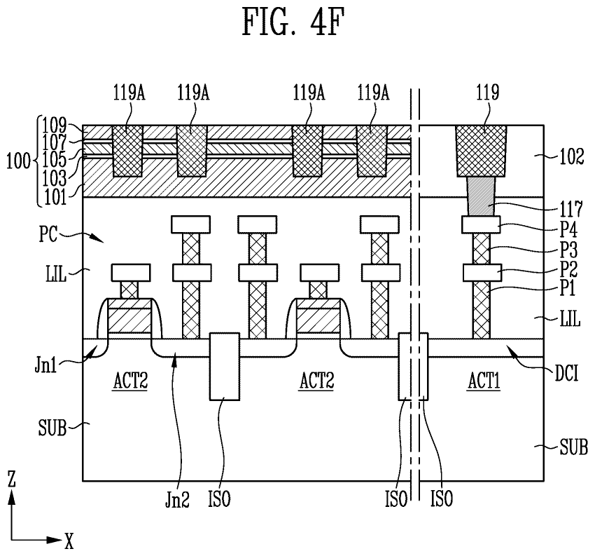

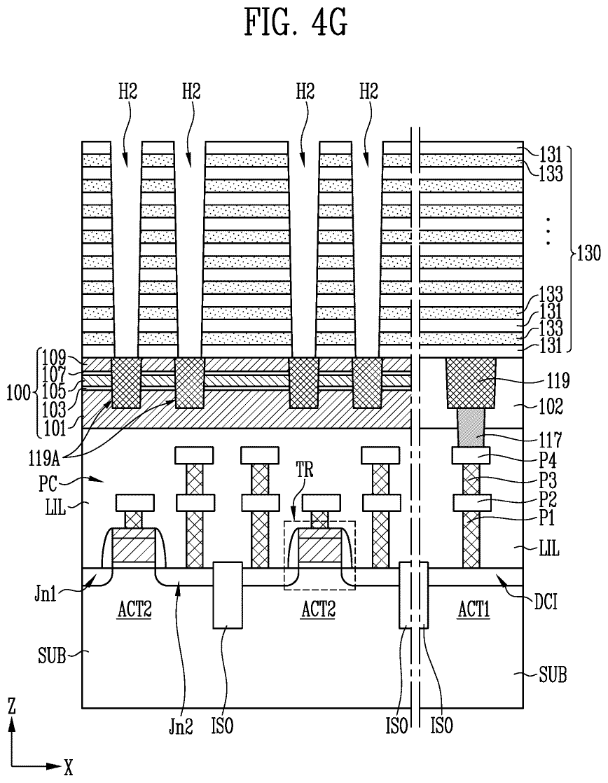

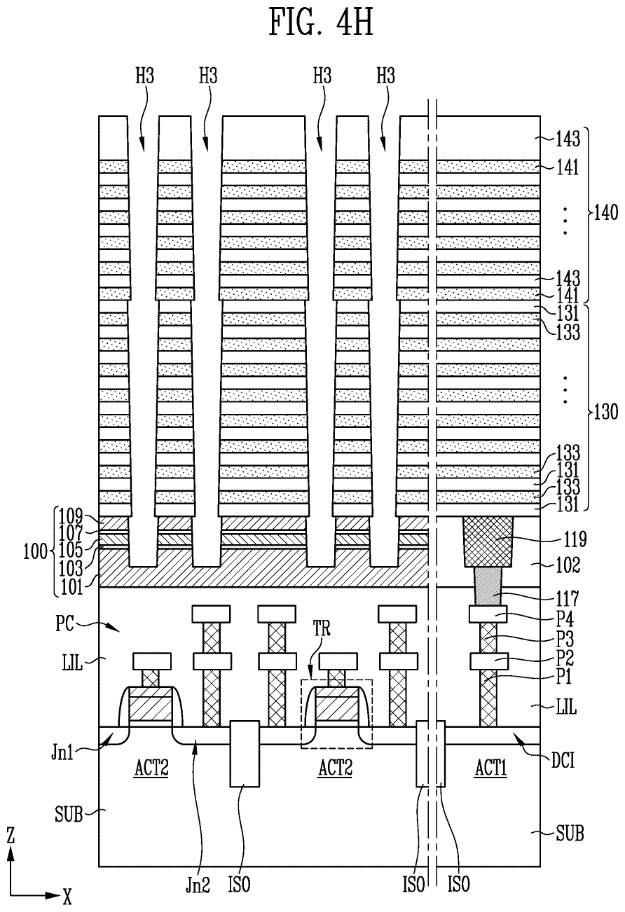

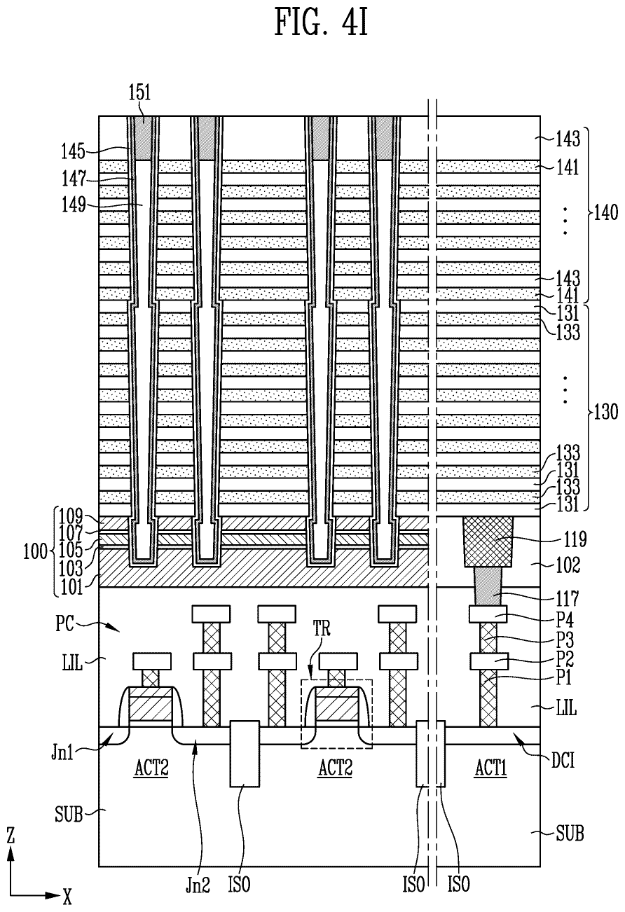

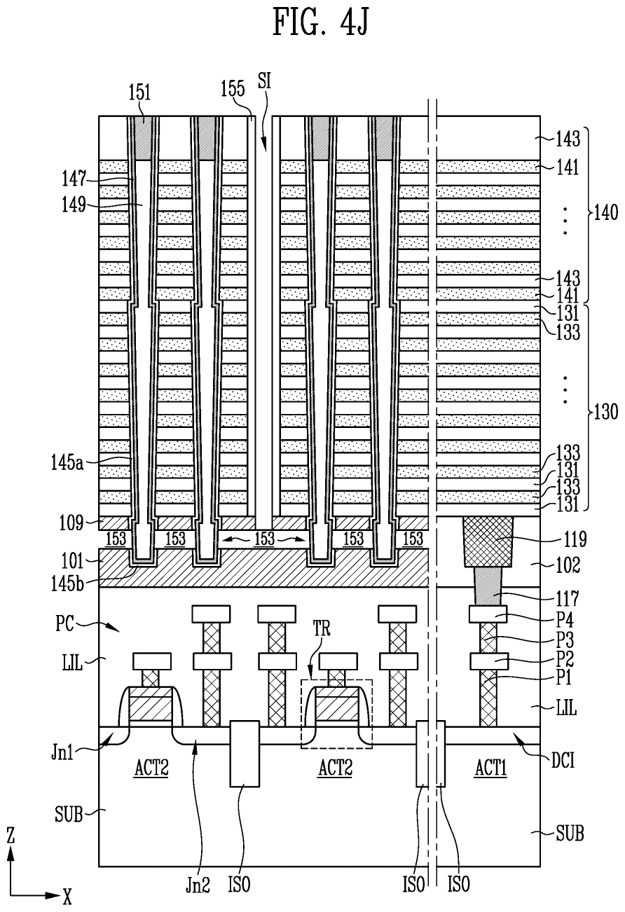

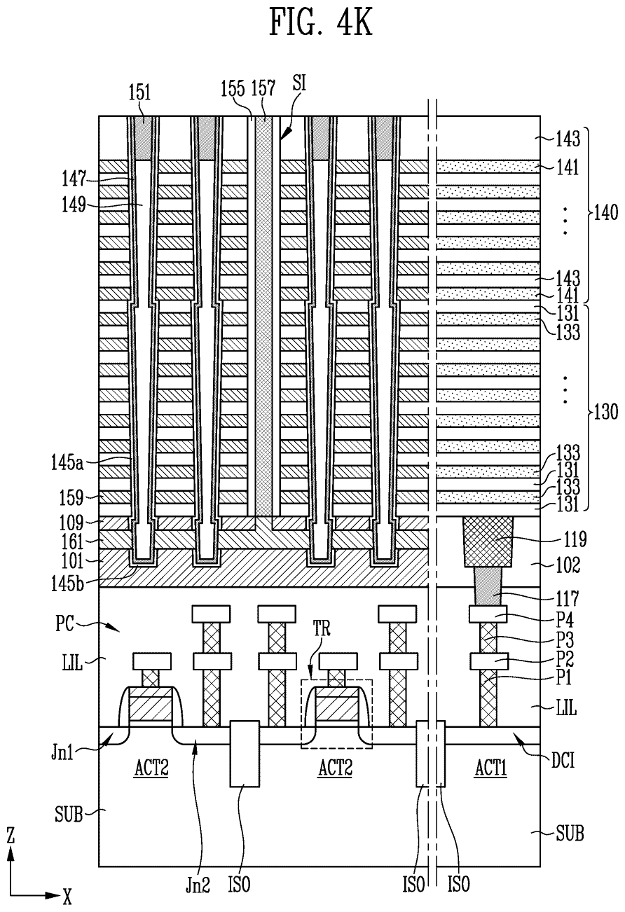

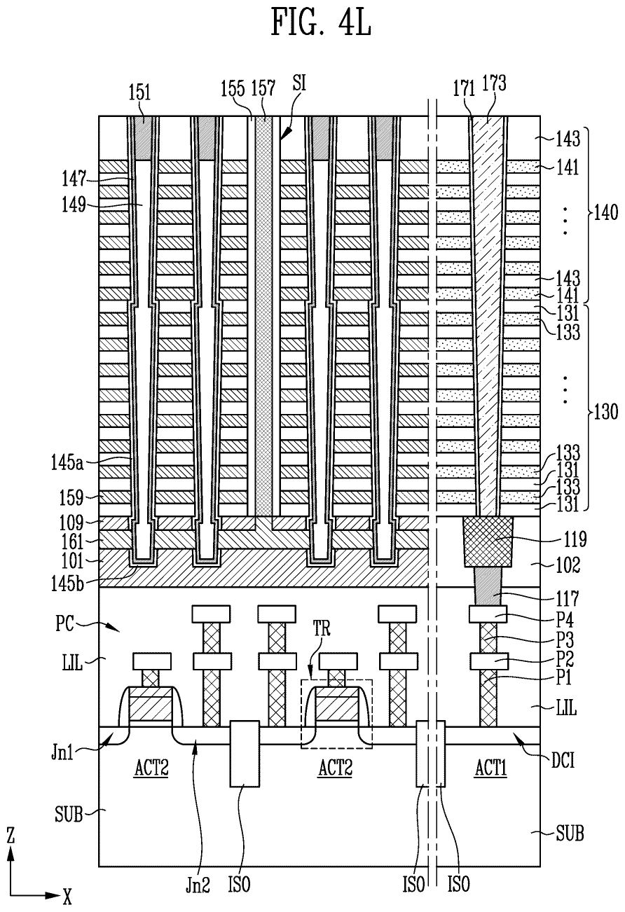

FIGS. 4A to 4L are sectional views and plan views for explaining a method of manufacturing a semiconductor device according to an embodiment of the present disclosure.

Referring to FIG. 4A, a peripheral circuit structure PC and first to fourth patterns P1 to P4 may be formed on a substrate SUB including active areas ACT1 and ACT2 partitioned by device isolation layers ISO. The peripheral circuit structure PC and the first to fourth patterns P1 to P4 may be covered by the lower insulating structure LIL.

The active areas ACT1 and ACT2 may include a first active area ACT1 and a second active area ACT2. The first active area ACT1 may include a discharge impurity area DCI, and the second active area ACT2 may include junctions Jn1 and Jn2. An area overlapping the first active area ACT1 may be defined as a discharge contact area, and an area overlapping the second active area ACT2 may be defined as a cell area.

Because the device isolation layers ISO, the active areas ACT1 and ACT2, the discharge impurity area DCI, the junctions Jn1 and Jn2, the peripheral circuit structure PC, and the lower insulating structure LIL have been described in detail with reference to FIGS. 1 and 2, a repeated description thereof will be omitted.

The first to fourth patterns P1 to P4 may be formed of a conductive material, and may be sequentially stacked on the discharge impurity area DCI. The first pattern P1 disposed on the lowest layer among the first to fourth patterns P1 to P4 may directly contact the discharge impurity area DCI.

Subsequently, a lower stacked body 100 may be formed on the lower insulating structure LIL. The lower stacked body 100 may include a lower semiconductor layer 101, a sacrificial layer 105, and an upper semiconductor layer 109 that are sequentially stacked. Before depositing the sacrificial layer 105 on the lower semiconductor layer 101, a first protective layer 103 may be formed on the lower semiconductor layer 101. Before the upper semiconductor layer 109 is formed on the lower semiconductor layer 101 or the first protective layer 103, a second protective layer 107 may be formed on the lower semiconductor layer 101 or the first protective layer 103.

The lower semiconductor layer 101 may include a doped semiconductor layer containing a conductive impurity. For example, the lower semiconductor layer 101 may include an n type doped silicon layer. The sacrificial layer 105 may include a material having an etch rate different from that of the first protective layer 103 and the second protective layer 107, and each of the first protective layer 103 and the second protective layer 107 may include a material having an etch rate different from that of the lower semiconductor layer 101 and the upper semiconductor layer 109. For example, the sacrificial layer 105 may include an undoped silicon layer, and each of the first protective layer 103 and the second protective layer 107 may include an oxide layer. The upper semiconductor layer 109 may include a semiconductor layer. For example, the upper semiconductor layer 109 may include a doped silicon layer or an undoped silicon layer.

Subsequently, the lower stacked body 100 formed on the first active area ACT1 or the contact area of the substrate SUB is removed by etching, and a source cutting insulating layer 102 is formed in a space where the lower stacked body 100 is removed. The source cutting insulating layer 102 may include an oxide layer. The source cutting insulating layer 102 may overlap the discharge impurity area DCI.

Referring to FIG. 4B, an opening 115 may be formed through a portion of the source cutting insulating layer 102 to expose the lower insulating structure LIL. The opening 115 may have various structures, such as a cylindrical shape, a prismatic shape, or a trench shape.

Referring to FIG. 4C, the opening 115 of FIG. 4B is filled with a conductive material to form a discharge contact 117. In an embodiment, the interior of the opening 115 may be filled with a sacrificial material.

Thereafter, a recess area R is formed by etching the upper end of the discharge contact 117 and a portion of the source cutting insulating layer 102. The depth of the recess area R may be formed to be deeper than the position of the first protective layer 103.

In addition, a plurality of holes H1 are formed by etching the lower stacked body 100 in an area of the cell area where the cell plugs are formed. The plurality of holes H1 may be formed together during an etching process for forming the recess area R. The plurality of holes H1 may be formed to pass through the upper semiconductor layer 109, the second protective layer 107, and the sacrificial layer 105. The plurality of holes H1 may be formed to extend into the first protective layer 103 and the lower semiconductor layer 101.

FIGS. 4D and 4E are plan views illustrating a plurality of recess areas in the process of forming the recess area R described above.

Referring to FIGS. 4D and 4E, a plurality of recess areas R1, R2, R3, and R4 may be formed by etching the upper end of the discharge contact 117 and a portion of the source cutting insulating layer 102 of FIG. 4C. The plurality of recess areas R1, R2, R3, and R4 may be arranged side by side in the first horizontal direction X, and each of the plurality of recess areas R1, R2, R3, and R4 may be formed to have a rectangular cross-section (FIG. 4D) or a circular cross-section (FIG. 4E). Further, each of the plurality of recess areas R2, R3, and R4 may be formed to have the extenders PT2, PT3, and PT4 extending in the second horizontal direction Y, and the lengths of the extenders PT2, PT3, and PT4 may be different from each other. In some embodiments, the lengths of the extenders PT2, PT3, and PT4 may be the same as each other. In some embodiments, some of the lengths of the extenders PT2, PT3, and PT4 may be the same as each other and some of the lengths of the extenders PT2, PT3, and PT4 may be different from each other. For example, the extender PT2 of the recess area R2 may extend by a first length X1, the extender PT3 of the recess area R3 may extend by a second length X2, and the extender PT4 of the recess area R4 may extend by a third length X3.

Referring to FIG. 4F, the recess area R of FIG. 4C is filled with the conductive material to form a contact pad 119. The contact pad 119 may include a metal material.

During the process of forming the contact pad 119, the conductive material may fill the first holes H1 of FIG. 4C formed on the cell area to form a sacrificial pattern 119A.

In the description related to FIG. 4C described above, when the opening 115 is filled with a sacrificial material, the sacrificial material may be removed, and a space where the sacrificial material has been removed may be filled with a conductive material to simultaneously form a discharge contact 117 and a contact pad 119. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Referring to FIG. 4G, a first upper stacked body 130 may be formed on an entire structure including the lower stacked body 100 and the source cutting insulating layer 102. The first upper stacked body 130 may include first material layers 131 and second material layers 133 that are alternately stacked. The first material layers 131 and the second material layers 133 are extended to overlap the contact pad 119 and the sacrificial pattern 119A.

The first material layers 131 may include a material different from the second material layers 133. In an embodiment, the first material layers 131 may include an insulating material, and the second material layers 133 may include a sacrificial insulating material having an etch rate different from that of the first material layers 131. For example, each of the first material layers 131 may include silicon oxide, and each of the second material layers 133 may include silicon nitride.

Thereafter, first channel holes H2 are formed through the first upper stacked body 130 to expose the sacrificial patterns 119A. During the etching process of the first upper stacked body 130 for forming the first channel holes H2, the sacrificial patterns 119A may prevent or mitigate the first channel holes H2 from passing through the lower stacked body 100. Further, in an embodiment, by using the sacrificial patterns 119A during the etching process of the first upper stacked body 130, the bottom surfaces of the first channel holes H2 may be etched to secure the critical dimension.

Referring to FIG. 4H, after the first channel holes H2 of FIG. 4G are filled with a sacrificial layer, a second upper stacked body 140 may be formed on the first upper stacked body 130. The second upper stacked body 140 may include first material layers 143 and second material layers 141 that are alternately stacked.

The first material layers 143 may include a material different from that of the second material layers 141. In an embodiment, the first material layers 143 may include an insulating material, and the second material layers 141 may include a sacrificial insulating material having an etch rate different from that of the first material layers 143. For example, each of the first material layers 143 may include silicon oxide, and each of the second material layers 141 may include silicon nitride. The first material layer 143 of the second upper stacked body 140 may be the same material as the first material layer 131 of the first upper stacked body 130, and the second material layer 141 of the second upper stacked body 140 may be the same material as the first material layer 143 of the first upper stacked body 130.

Thereafter, second channel holes H3 are formed through the second upper stacked body 140 to expose the sacrificial layer filling the first channel holes H2 of FIG. 4G. Then, the sacrificial layer and the sacrificial patterns 119A of FIG. 4G are removed. Thus, the second channel holes H3 extend into the first upper stacked body 130 and the lower stacked body 100. The second channel holes H3 each have a bottleneck pattern at a boundary between the first upper stacked body 130 and the lower stacked body 100.

Referring to FIG. 4I, a memory layer 145 may be conformally formed on the surface of each of the second channel holes H3 of FIG. 4H. The memory layer 145 may include a tunnel isolation layer, a data storage layer, and a blocking insulating layer.

A channel semiconductor layer 147 may be formed in a central area of each of the second channel holes opened by the memory layer 145. The channel semiconductor layer 147 may be formed in a pillar shape to fill the central area of each of the second channel holes opened by the memory layer 145. Alternatively, the channel semiconductor layer 147 may be conformally formed along the surface of the memory layer 145, and the central area of each of the second channel holes may be opened by the channel semiconductor layer 147. The central area of each of the second channel holes opened by the channel semiconductor layer 147 may be filled with a core insulating layer 149. The core insulating layer 149 may be formed to have a lower height than the channel semiconductor layer 147 and the second channel holes. In this case, the doped semiconductor pattern 151 may be formed on the core insulating layer 149. The doped semiconductor pattern 151 may be enclosed or surrounded by the upper end of the channel semiconductor layer 147 that extends longer than the core insulating layer 149.

The channel semiconductor layer 147 may include a silicon layer. The doped semiconductor pattern 151 may include an n type doped silicon layer. The core insulating layer 149 may include oxide.

Referring to FIG. 4J, a slit SI is formed to pass through the second upper stacked body 140 and the first upper stacked body 130 formed on the cell area, and a sidewall insulating layer 155 is formed on the sidewall of the slit SI. The sidewall insulating layer 155 may be formed to expose the bottom surface of the slit SI. The upper semiconductor layer 109 may be exposed through the bottom surface of the slit SI exposed by the sidewall insulating layer 155.

Thereafter, the upper semiconductor layer 109 and the second protective layer 107 exposed through the slit SI are etched to expose the sacrificial layer 105 (see FIG. 41) on the cell area.

Subsequently, the exposed sacrificial layer 105 is removed to form a horizontal space 153. During the process of removing the sacrificial layer 105 on the cell area, the first protective layer 103 (see FIG. 4I) and the second protective layer 107 (see FIG. 41) in the cell area may prevent or mitigate the loss of the upper semiconductor layer 109 and the lower semiconductor layer 101.

Thereafter, the channel semiconductor layer 147 is exposed by etching a portion of the memory layer exposed through the horizontal space 153. The memory layer may be separated into a first memory pattern 145a and a second memory pattern 145b through the etching process.

During the etching process of the memory layer, the first protective layer 103 (see FIG. 41) and the second protective layer 107 (see FIG. 4I) may be removed together.

Referring to FIG. 4K, a conductive material is introduced into the horizontal space 153 of FIG. 4J through the slit SI to form a source semiconductor layer 161. The source semiconductor layer 161 may contact the sidewall of the channel semiconductor layer 147, the lower semiconductor layer 101, and the upper semiconductor layer 109. The source semiconductor layer 161 may be formed using a chemical vapor deposition method, or formed using a growth method using each of the channel semiconductor layer 147, the lower semiconductor layer 101, and the upper semiconductor layer 109 as a seed layer. The source semiconductor layer 161 may include a conductive dopant. For example, the source semiconductor layer 161 may include an n type doped silicon layer. In an embodiment, the conductive dopant in the source semiconductor layer 161 may diffuse into the upper semiconductor layer 109 and the channel semiconductor layer 145 contacting the source semiconductor layer 161 due to heat.

Thereafter, the interior of the slit SI may be filled with a conductive material to form a source contact structure 157 that contacts the source semiconductor layer 161 and extends onto the sidewall insulating layer 155.

The etching process is performed to expose sidewalls of the first upper stacked body 130 and the second upper stacked body 140 stacked on the cell area, and the second material layer of the first upper stacked body 130 and the second material layer of the second upper stacked body 140 exposed through the etching process are removed. Thereafter, spaces where the second material layer of the first upper stacked body 130 and the second material layer of the second upper stacked body 140 are removed are filled with the conductive material to form gate patterns 159 for word lines.

Referring to FIG. 4L, a contact plug 173 is formed through the first upper stacked body 130 and the second upper stacked body 140 stacked on the source cutting insulating layer 102 to contact the top of the contact pad 119.

For example, a contact hole is formed through the first upper stacked body 130 and the second upper stacked body 140 stacked on the source cutting insulating layer 102 to expose a portion of the top of the contact pad 119, and a barrier layer 171 is formed along the sidewall of the contact hole. Thereafter, the interior of the contact hole may be filled with a conductive material to form the contact plug 173.

The semiconductor device shown in FIGS. 2 and 3 may be formed using the process shown in FIGS. 4A to 4L.

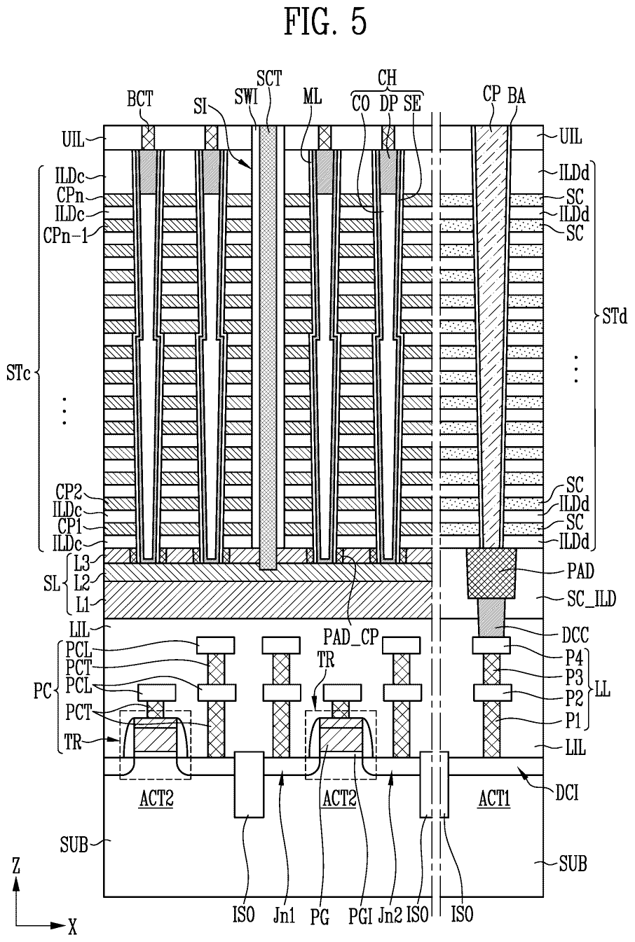

FIG. 5 is a sectional view illustrating a semiconductor device according to embodiments of the present disclosure.

Referring to FIG. 5, the semiconductor device may include a source layer SL disposed on a substrate SUB, and a cell stacked layer STc disposed on the source layer SL. The semiconductor device may include a source cutting insulating layer SC_ILD disposed on the substrate SUB, a dummy stacked body STd disposed on the source cutting insulating layer SC_ILD, a contact plug CP extending in the dummy stacked body STd in a vertical direction Z to contact an upper surface of a contact pad PAD, and a discharge contact DCC contacting a lower surface of the contact pad PAD and extending downwards. The source layer SL and the source cutting insulating layer SC_ILD may be disposed adjacent to each other on the same level in a first horizontal direction X.

The substrate SUB may be formed of the same material as the substrate SUB described above with reference to FIG. 1. Conductive dopants defining a well area may be implanted into the substrate SUB. The conductive dopant defining the well area may be an n-type or p-type impurity. The well area of the substrate SUB may be divided into active areas ACT1 and ACT2 partitioned by device isolation layers ISO. The device isolation layers ISO may include an insulating material embedded in the substrate SUB. The active areas ACT1 and ACT2 may include a first active area ACT1 overlapping the discharge contact DCC, and one or more second active areas ACT2 overlapping the cell stacked layer STC.

The source layer SL and the source cutting insulating layer SC_ILD may be arranged to be spaced apart from the substrate SUB by the peripheral circuit structure PC and a lower insulating structure LIL. The source layer SL and the source cutting insulating layer SC_ILD may be disposed adjacent to each other at the same height. For example, the source layer SL and the source cutting insulating layer SC_ILD may be disposed adjacent to each other at an identical level as shown in FIG. 2. For example, the source layer SL may be disposed on the cell area of the substrate SUB, and the source cutting insulating layer SC_ILD may be disposed on the contact area of the substrate SUB.

The peripheral circuit structure PC may include a transistor TR described with reference to FIG. 1. The transistor TR may include a peripheral-gate insulating layer PGI disposed on the second active area ACT2, a peripheral-gate electrode PG disposed on the peripheral-gate insulating layer PGI, and first and second junctions Jn1 and Jn2 disposed in the second active area ACT2 on opposite sides of the peripheral-gate electrode PG. The first and second junctions Jn1 and Jn2 may be areas defined by implanting the n-type or p-type impurity into the second active area ACT2. One may be used as a source junction, while the other may be used as a drain junction.

The peripheral circuit structure PC may include connecting lines PCL and peripheral-contact plugs PCT connected to the transistor TR. The peripheral circuit structure PC may include a resistor, a capacitor, etc. as described with reference to FIG. 1, in addition to the transistor TR and the connecting lines PCL and the peripheral-contact plugs PCT connected thereto.

The conductive impurity may be implanted into the first active area ACT1. In an embodiment, a discharge impurity area DCI may be defined in the first active area ACT1. The discharge impurity area DCI may include conductive impurities forming a PN diode.

The above-described peripheral circuit structure PC may be covered with a lower insulating structure LIL disposed between the source layer SL and the source cutting insulating layer SC_ILD and the substrate SUB. The lower insulating structure LIL may be extended to cover the discharge impurity area DCI. The lower insulating structure LIL may include insulating layers stacked in multiple layers.

The source layer SL may be disposed on the lower insulating structure LIL. The source layer SL may include two or more semiconductor layers L1, L2, and L3. For example, the source layer SL may include first to third semiconductor layers L1 to L3 that are sequentially stacked on the lower insulating structure LIL. The first and second semiconductor layers L1 and L2 each may be a doped semiconductor layer containing the source dopant. In an embodiment, each of the first and second semiconductor layers L1 and L2 may include a doped silicon layer containing the n type impurity. The third semiconductor layer L3 may be omitted in some cases. The third semiconductor layer L3 may include at least one of an n type doped silicon layer and an undoped silicon layer.

For example, the source cutting insulating layer SC_ILD may be penetrated by the contact pad PAD and the discharge contact DCC. Although one contact pad PAD and one discharge contact DCC are illustrated in the drawing, each of the contact pad PAD and the discharge contact DCC may be arranged to include multiple ones.

The discharge contact DCC may be connected to the lower line LL penetrating the lower insulating structure LIL to contact the discharge impurity area DCI of the substrate SUB. The lower line LL may include a plurality of lines P4 and P2 and a plurality of contacts P3 and P1.

The dummy stacked body STd may overlap the source cutting insulating layer SC_ILD and the contact pad PAD. The dummy stacked body STd may extend to cover the source cutting insulating layer SC_ILD and the contact pad PAD. The dummy stacked body may include dummy interlayer insulating layers ILDd and sacrificial insulating layers SC that are alternately stacked on the source cutting insulating layer SC_ILD and the contact pad PAD. The contact plug CP may penetrate the dummy stacked body STd in the vertical direction Z to be connected to the contact pad PAD, and a barrier layer BA may be formed on the sidewall of the contact plug CP.

The cell stacked layer STc may include cell interlayer insulating layers ILDc and conductive patterns CP1 to CPn (n is a natural number of 2 or more) that are alternately stacked on the source layer SL. The cell stacked layer STc may be arranged not to overlap the source cutting insulating layer SC_ILD and the contact pad PAD. The cell stacked layer STc may be disposed on the same level as the dummy stacked body STd. The cell interlayer insulating layers ILDc may be disposed on the same levels as the dummy interlayer insulating layers ILDd, and the conductive patterns CP1 to CPn may be disposed on the same levels as the sacrificial insulating layers SC.

The cell interlayer insulating layers ILDc and the dummy interlayer insulating layers ILDd may be formed of the same material, and formed through the same process. The sacrificial insulating layers SC may be formed of a material having an etch rate different from that of the cell interlayer insulating layers ILDc and the dummy interlayer insulating layers ILDd. For example, the cell interlayer insulating layers ILDc and the dummy interlayer insulating layers ILDd may include silicon oxide, and the sacrificial insulating layers SC may include silicon nitride.

Each of the conductive patterns CP1 to CPn may include various conductive materials such as a doped silicon layer, a metal layer, a metal silicide layer, and a barrier layer, and may include two or more types of conductive materials. For example, each of the conductive patterns CP1 to CPn may include tungsten and a titanium nitride layer (TiN) surrounding the surface of tungsten. Tungsten is a low-resistance metal, and may lower the resistance of the conductive patterns CP1 to CPn. The titanium nitride layer TiN is a barrier layer, and may prevent or mitigate direct contact between tungsten and the cell interlayer insulating layers ILDc.

The conductive patterns CP1 to CPn may be used as the gate electrodes of the cell string. The gate electrodes of the cell string may include source select lines, word lines, and drain select lines. The source select lines may be used as the gate electrodes of the source select transistors, the drain select lines may be used as the gate electrodes of the drain select transistors, and the word lines may be used as the gate electrodes of the memory cells.

The cell stacked layer STc may enclose or surround the channel structure CH. That is, the channel structure CH may penetrate a portion of the cell stacked layer STc and the source layer SL. The channel structure CH may include a channel semiconductor layer SE. The channel semiconductor layer SE may include a silicon layer. The central area of the channel semiconductor layer SE may be filled with the core insulating layer CO. The core insulating layer CO may be formed to have a height lower than that of the channel semiconductor layer SE. A top central area of the channel semiconductor layer SE extending further upwards than the core insulating layer CO may be filled with a doped semiconductor pattern DP disposed on the core insulating layer CO. The doped semiconductor pattern DP may include the n type doped silicon layer. The channel semiconductor layer SE of the channel structure CH may be used as the channel area of the cell string, and the doped semiconductor pattern DP of the channel structure CH may be used as the drain junction of the cell string. The sidewall of the channel structure CH may be enclosed with a memory layer ML.

The channel structure CH may penetrate the cell stacked layer STc, and extend into the source layer SL. The lower surface of the channel structure CH overlapping the source layer SL may directly contact the source layer SL. In an embodiment, the second semiconductor layer L2 of the source layer SL may directly contact an end of the channel semiconductor layer SE. A pad PAD_CP for the cell plug may be disposed between the channel structure CH and the third semiconductor layer L3. For example, the pad PAD_CP for the cell plug may be formed to enclose a lower end of the channel structure CH. The pad PAD_CP for the cell plug may be formed of the same material as the contact pad PAD.

The slit SI may be filled with a source contact structure SCT. The source contact structure SCT may be spaced apart from the cell stacked layer STc by a sidewall insulating layer SWI formed on the sidewall of the slit SI. The sidewall insulating layer SWI may be penetrated by the source contact structure SCT. The source contact structure SCT may extend to contact the source layer SL. The source contact structure SCT may include a single conductive material or two or more types of conductive materials. The conductive material for the source contact structure SCT may include a doped silicon layer, a metal layer, a metal silicide layer, a barrier layer, etc. For example, the source contact structure SCT may include a doped silicon layer contacting the source layer SL and a metal layer disposed on the doped silicon layer.

An upper insulating structure UIL may include a single insulating layer or two or more insulating layers. For example, the upper insulating structure UIL may include an oxide layer. The upper insulating structure UIL may be penetrated by a bit line contact plug BCT. The bit line contact plug BCT may be connected to the doped semiconductor pattern DP of the channel structure CH.

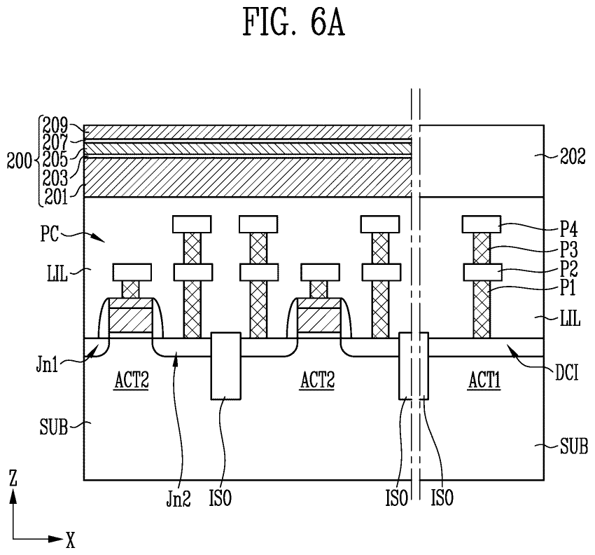

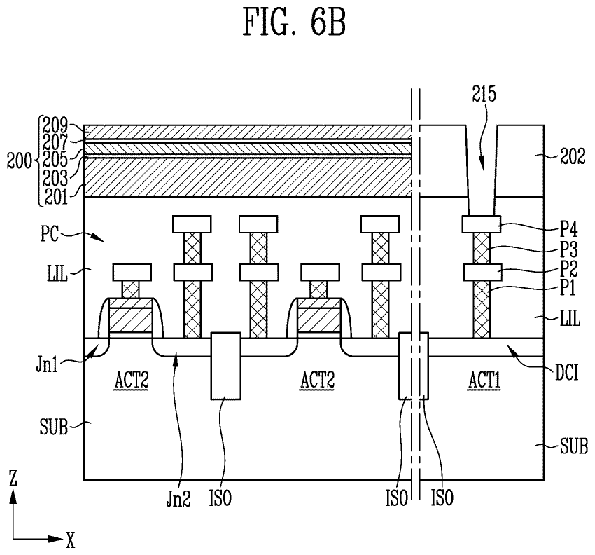

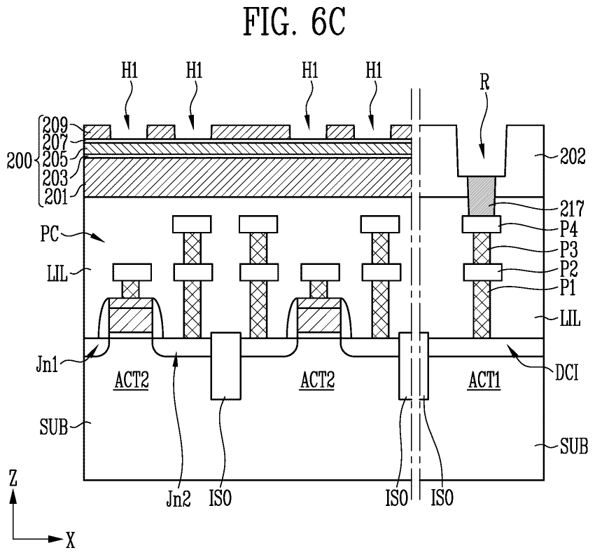

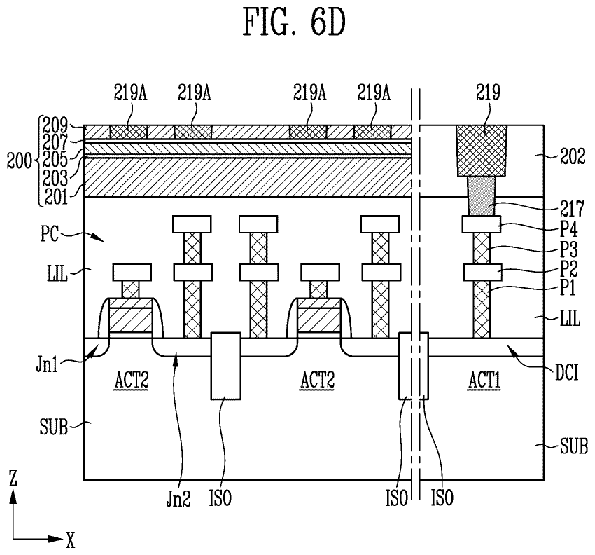

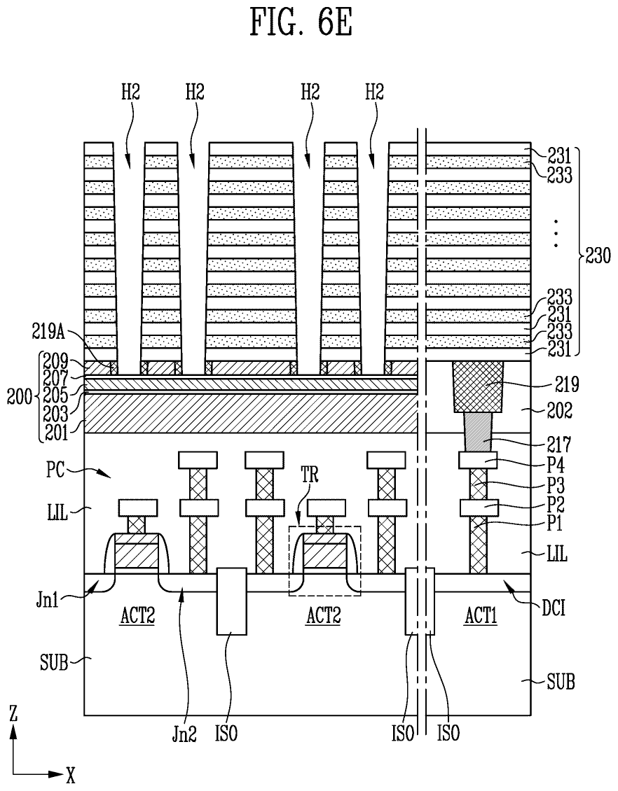

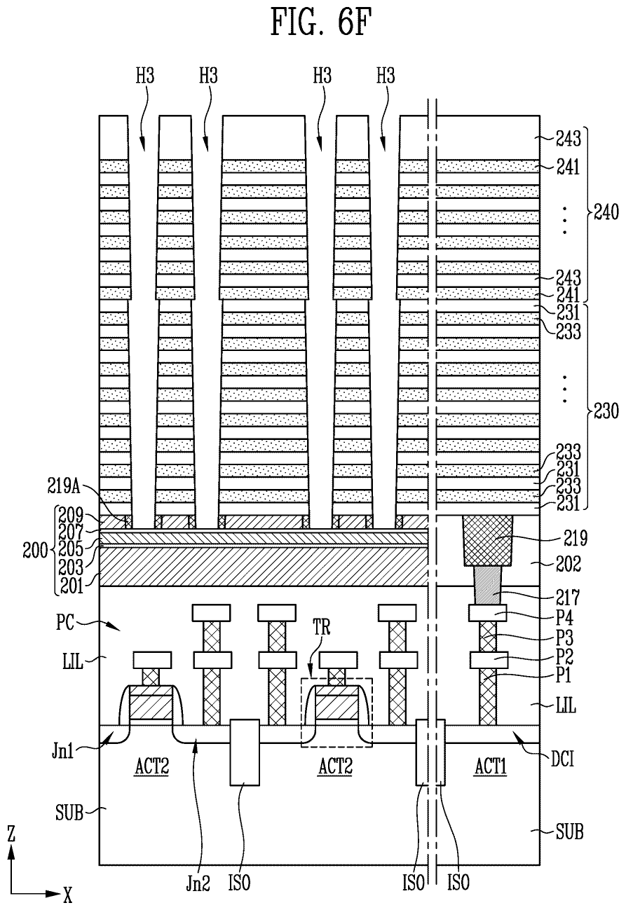

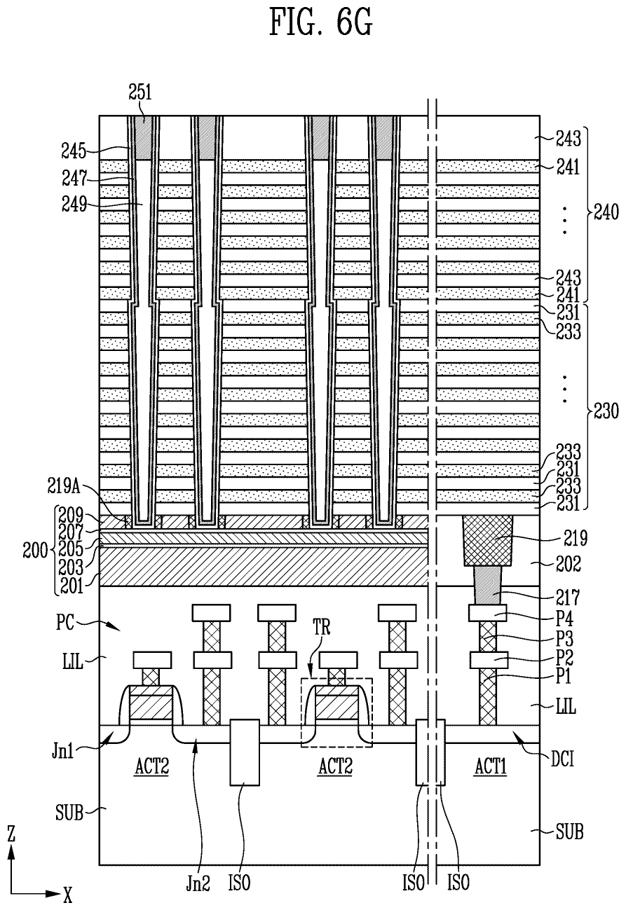

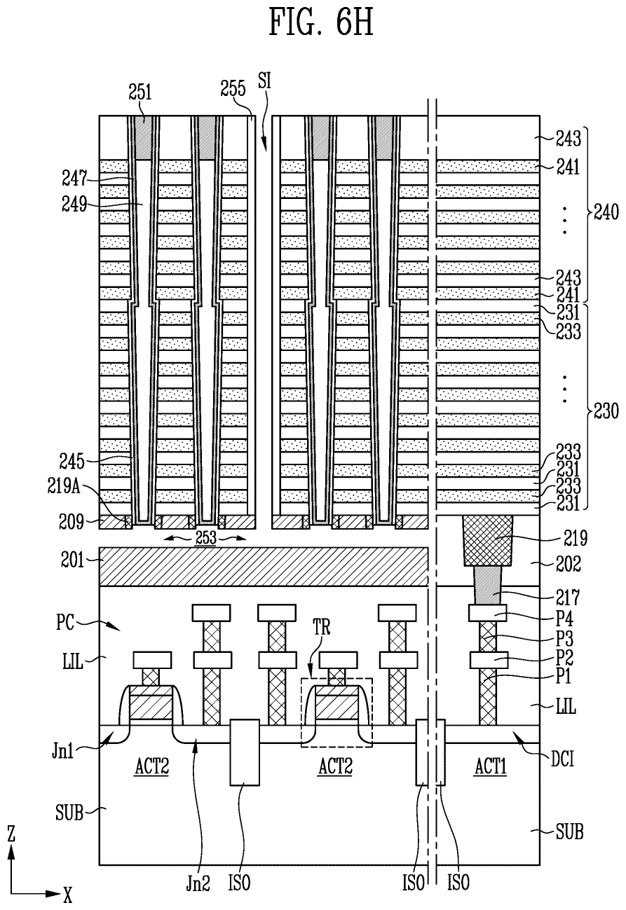

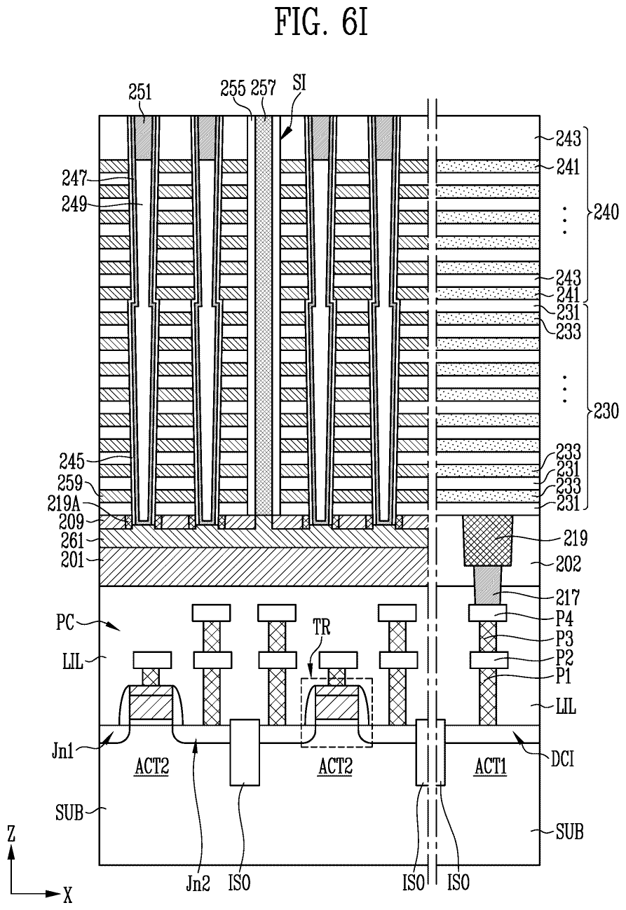

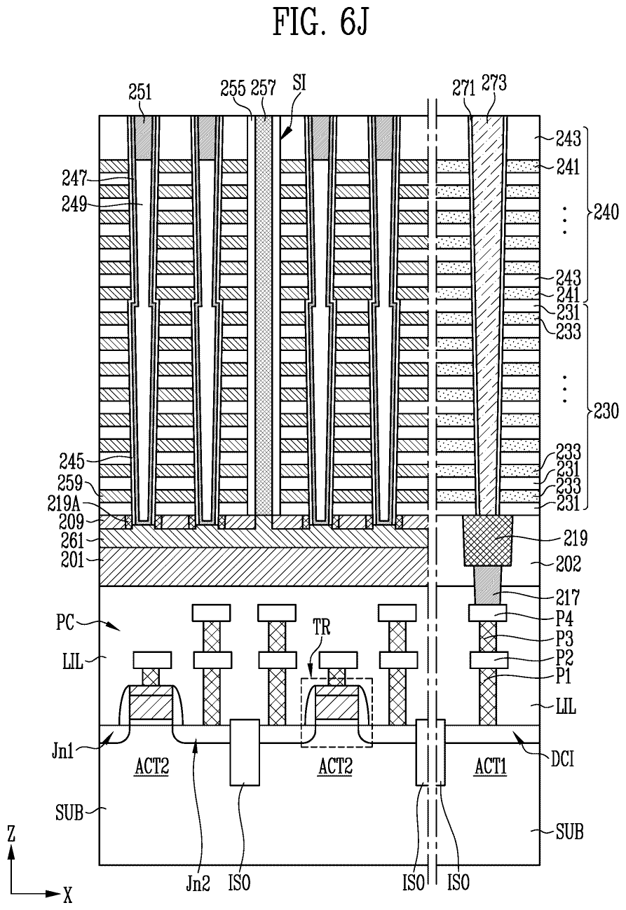

FIGS. 6A to 6J are sectional views for explaining a method of manufacturing a semiconductor device according to an embodiment of the present disclosure.

Referring to FIG. 6A, a peripheral circuit structure PC and first to fourth patterns P1 to P4 may be formed on a substrate SUB including active areas ACT1 and ACT2 partitioned by device isolation layers ISO. The peripheral circuit structure PC and the first to fourth patterns P1 to P4 may be covered by the lower insulating structure LIL.

The active areas ACT1 and ACT2 may include a first active area ACT1 and a second active area ACT2. The first active area ACT1 may include a discharge impurity area DCI, and the second active area ACT2 may include junctions Jn1 and Jn2. An area overlapping the first active area ACT1 may be defined as a discharge contact area, and an area overlapping the second active area ACT2 may be defined as a cell area.

Because the device isolation layers ISO, the active areas ACT1 and ACT2, the discharge impurity area DCI, the junctions Jn1 and Jn2, the peripheral circuit structure PC, and the lower insulating structure LIL have been described in detail with reference to FIG. 5, a repeated description thereof will be omitted.

The first to fourth patterns P1 to P4 may be formed of a conductive material, and may be sequentially stacked on the discharge impurity area DCI. The first pattern P1 disposed on the lowest layer among the first to fourth patterns P1 to P4 may directly contact the discharge impurity area DCI.

Subsequently, a lower stacked body 200 may be formed on the lower insulating structure LIL. The lower stacked body 200 may include a lower semiconductor layer 201, a sacrificial layer 205, and an upper semiconductor layer 209 that are sequentially stacked. Before depositing the sacrificial layer 205 on the lower semiconductor layer 201, a first protective layer 203 may be formed on the lower semiconductor layer 201. Before the upper semiconductor layer 209 is formed on the lower semiconductor layer 201 or the first protective layer 203, a second protective layer 207 may be formed on the lower semiconductor layer 201 or the first protective layer 203.

The lower semiconductor layer 201 may include a doped semiconductor layer containing a conductive impurity. For example, the lower semiconductor layer 201 may include an n type doped silicon layer. The sacrificial layer 205 may include a material having an etch rate different from that of the first protective layer 203 and the second protective layer 207, and each of the first protective layer 203 and the second protective layer 207 may include a material having an etch rate different from that of the lower semiconductor layer 201 and the upper semiconductor layer 209. For example, the sacrificial layer 205 may include an undoped silicon layer, and each of the first protective layer 203 and the second protective layer 207 may include an oxide layer. The upper semiconductor layer 209 may include a semiconductor layer. For example, the upper semiconductor layer 209 may include a doped silicon layer or an undoped silicon layer.

Subsequently, the lower stacked body 200 formed on the first active area ACT1 or the contact area of the substrate SUB is removed by etching, and a source cutting insulating layer 202 is formed in a space where the lower stacked body 200 is removed. The source cutting insulating layer 202 may include an oxide layer. The source cutting insulating layer 202 may overlap the discharge impurity area DCI.

Referring to FIG. 6B, an opening 215 may be formed through a portion of the source cutting insulating layer 202 to expose the lower insulating structure LIL. The opening 215 may have various structures, such as a cylindrical shape, a prismatic shape, or a trench shape.

Referring to FIG. 6C, the opening 215 of FIG. 6B is filled with a conductive material to form a discharge contact 217. In an embodiment, the interior of the opening 215 may be filled with a sacrificial material.

Thereafter, a recess area R is formed by etching the upper end of the discharge contact 217 and a portion of the source cutting insulating layer 202. The depth of the recess area R may be formed to be deeper than the position of the first protective layer 203.

In addition, a plurality of holes H1 are formed by etching the lower stacked body 200 in an area of the cell area where the cell plugs are formed. The plurality of holes H1 may be formed together during an etching process for forming the recess area R. The plurality of holes H1 may be formed to pass through the upper semiconductor layer 209 and thereby expose a portion of the second protective layer 207.

Referring to FIG. 6D, the recess area R of FIG. 6C is filled with the conductive material to form a contact pad 219. The contact pad 219 may include a metal material.

During the process of forming the contact pad 219, the conductive material may fill the first holes H1 of FIG. 6C formed on the cell area to form a pad 219A for a cell plug. In some embodiments, a pad 219A may be referred to as a cell plug pad.

In the description related to FIG. 6C described above, when the opening 215 is filled with a sacrificial material, the sacrificial material may be removed, and a space where the sacrificial material has been removed may be filled with a conductive material to simultaneously form a discharge contact 217 and a contact pad 219.

Referring to FIG. 6E, a first upper stacked body 230 may be formed on an entire structure including the lower stacked body 200 and the source cutting insulating layer 202. The first upper stacked body 230 may include first material layers 231 and second material layers 233 that are alternately stacked. The first material layers 231 and the second material layers 233 are extended to overlap the contact pad 219 and the pad 219A for the cell plug.

The first material layers 231 may include a material different from the second material layers 233. In an embodiment, the first material layers 231 may include an insulating material, and the second material layers 233 may include a sacrificial insulating material having an etch rate different from that of the first material layers 231. For example, each of the first material layers 231 may include silicon oxide, and each of the second material layers 233 may include silicon nitride.

Thereafter, first channel holes H2 are formed through the first upper stacked body 230 and the pad 219A for the cell plug to expose the second protective layer 207.

During the etching process of the first upper stacked body 230 for forming the first channel holes H2, the pad 219A for the cell plug may prevent or mitigate the first channel holes H2 from passing through the lower stacked body 200. Further, by using the pad 219A for the cell plug during the etching process of the first upper stacked body 230, the bottom surfaces of the first channel holes H2 may be etched to sufficiently secure the critical dimension.

Referring to FIG. 6F, after the first channel holes H2 of FIG. 6E are filled with a sacrificial layer, a second upper stacked body 240 may be formed on the first upper stacked body 230. The second upper stacked body 240 may include first material layers 243 and second material layers 241 that are alternately stacked.

The first material layers 243 may include a material different from that of the second material layers 241. In an embodiment, the first material layers 243 may include an insulating material, and the second material layers 241 may include a sacrificial insulating material having an etch rate different from that of the first material layers 243. For example, each of the first material layers 243 may include silicon oxide, and each of the second material layers 241 may include silicon nitride. The first material layer 243 of the second upper stacked body 240 may be the same material as the first material layer 231 of the first upper stacked body 230, and the second material layer 241 of the second upper stacked body 240 may be the same material as the first material layer 243 of the first upper stacked body 230.

Thereafter, second channel holes H3 are formed through the second upper stacked body 240 to expose the sacrificial layer filling the first channel holes H2 of FIG. 6E. Then, the sacrificial layer is removed. Thus, the second channel holes H3 extend into the first upper stacked body 230 and the lower stacked body 200.

Referring to FIG. 6G, a memory layer 245 may be conformally formed on the surface of each of the second channel holes H3 of FIG. 6F. The memory layer 245 may include a tunnel isolation layer, a data storage layer, and a blocking insulating layer.

A channel semiconductor layer 247 may be formed in a central area of each of the second channel holes opened by the memory layer 245. The channel semiconductor layer 247 may be formed in a pillar shape to fill the central area of each of the second channel holes opened by the memory layer 245. Alternatively, the channel semiconductor layer 247 may be conformally formed along the surface of the memory layer 245, and the central area of each of the second channel holes may be opened by the channel semiconductor layer 247. The central area of each of the second channel holes opened by the channel semiconductor layer 247 may be filled with a core insulating layer 249. The core insulating layer 249 may be formed to have a lower height than the channel semiconductor layer 247 and the second channel holes. In this case, the doped semiconductor pattern 251 may be formed on the core insulating layer 249. The doped semiconductor pattern 251 may be enclosed by the upper end of the channel semiconductor layer 247 that extends longer than the core insulating layer 249.

The channel semiconductor layer 247 may include a silicon layer. The doped semiconductor pattern 251 may include an n type doped silicon layer. The core insulating layer 249 may include oxide.

Referring to FIG. 6H, a slit SI is formed to pass through the second upper stacked body 240 and the first upper stacked body 230 formed on the cell area, and a sidewall insulating layer 255 is formed on the sidewall of the slit SI. The sidewall insulating layer 255 may be formed to expose the bottom surface of the slit SI. The upper semiconductor layer 209 may be exposed through the bottom surface of the slit SI exposed by the sidewall insulating layer 255.

Thereafter, the upper semiconductor layer 209 and the second protective layer 207 (see FIG. 6G) exposed through the slit SI are etched to expose the sacrificial layer 205 (see FIG. 6G) on the cell area.

Subsequently, the exposed sacrificial layer 205 is removed to form a horizontal space 253. During the process of removing the sacrificial layer 205 on the cell area, the first protective layer 203 (see FIG. 6G) and the second protective layer 207 (see FIG. 6G) in the cell area may prevent or mitigate the loss of the upper semiconductor layer 209 and the lower semiconductor layer 201.

Thereafter, the first protective layer 203 (see FIG. 6G) and the second protective layer 207 (see FIG. 6G) exposed through the horizontal space 253 are removed, and the memory layer 245 exposed by removing the second protective layer 207 (see FIG. 6G) is removed, thereby exposing the bottom surface of the channel semiconductor layer 247.

Referring to FIG. 61, a conductive material is introduced into the horizontal space 253 of FIG. 6K through the slit SI to form a source semiconductor layer 261. The source semiconductor layer 261 may contact the lower surface of the channel semiconductor layer 247. The source semiconductor layer 261 may be formed using a chemical vapor deposition method, or formed using a growth method using each of the channel semiconductor layer 247, the lower semiconductor layer 201, and the upper semiconductor layer 209 as a seed layer. The source semiconductor layer 261 may include a conductive dopant. For example, the source semiconductor layer 261 may include an n type doped silicon layer. The conductive dopant in the source semiconductor layer 261 may diffuse into the upper semiconductor layer 209 and the channel semiconductor layer 245 contacting the source semiconductor layer 261 due to heat.

Thereafter, the interior of the slit SI may be filled with a conductive material to form a source contact structure 257 that contacts the source semiconductor layer 261 and extends onto the sidewall insulating layer 255.

The etching process is performed to expose sidewalls of the first upper stacked body 230 and the second upper stacked body 240 stacked on the cell area, and the second material layer of the first upper stacked body 230 and the second material layer of the second upper stacked body 240 exposed through the etching process are removed. Thereafter, spaces where the second material layer of the first upper stacked body 230 and the second material layer of the second upper stacked body 240 are removed are filled with the conductive material to form gate patterns 259 for word lines.

Referring to FIG. 6J, a contact plug 273 is formed through the first upper stacked body 230 and the second upper stacked body 240 stacked on the source cutting insulating layer 202 to contact the top of the contact pad 219.

For example, a contact hole is formed through the first upper stacked body 230 and the second upper stacked body 240 stacked on the source cutting insulating layer 202 to expose a portion of the top of the contact pad 219, and a barrier layer 271 is formed along the sidewall of the contact hole. Thereafter, the interior of the contact hole may be filled with a conductive material to form the contact plug 273.

The semiconductor device shown in FIG. 5 may be formed using the process shown in FIGS. 6A to 6J.

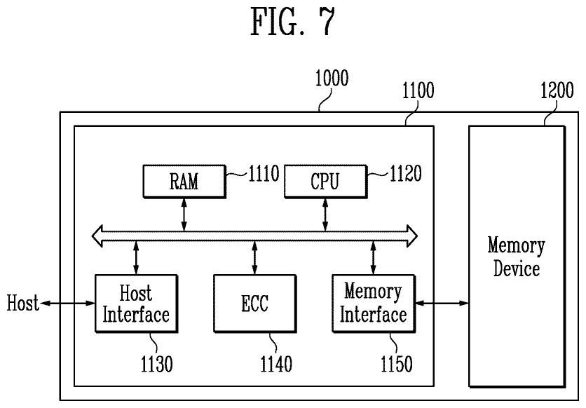

FIG. 7 is a block diagram illustrating the configuration of a memory system according to an embodiment of the present disclosure.

Referring to FIG. 7, a memory system 1000 according to the embodiment of the present disclosure includes a memory device 1200 and a controller 1100.

The memory device 1200 may be used to store data information having a variety of data formats such as text, graphics, and software codes. The memory device 1200 may be a semiconductor device, described above with reference to FIGS. 1 to 3, and may be manufactured according to the manufacturing methods, described above with reference to FIGS. 4A to 41 or FIGS. 6A to 6J. Because the structure of the memory device 1200 and the manufacturing method thereof are the same as those described above, detailed description thereof will be omitted.

The controller 1100 may be connected to a host and the memory device 1200, and may access the memory device 1200 in response to a request from the host. For example, the controller 1100 may control read, write, erase, and background operations of the memory device 1200.

The controller 1100 includes random access memory (RAM) 1110, central processing unit (CPU) 1120, a host interface 1130, an error correction code (ECC) circuit 1140, a memory interface 1150, etc.

Here, the RAM 1110 may be used as a working memory of the CPU 1120, a cache memory between the memory device 1200 and the host, a buffer memory between the memory device 1200 and the host, or the like. For reference, the RAM 1110 may be replaced with a static random access memory (SRAM), a read only memory (ROM), or the like.

The CPU 1120 may control the overall operation of the controller 1100. For example, the CPU 1120 may operate firmware such as a flash translation layer (FTL) stored in the RAM 1110.

The host interface 1130 may perform interfacing with the host. In an embodiment, the controller 1100 may communicate with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, and a private protocol.

The ECC circuit 1140 may use an error correction code (ECC) to detect and correct errors in data read from the memory device 1200.

The memory interface 1150 may perform interfacing with the memory device 1200. For example, the memory interface 1150 includes a NAND interface or a NOR interface.

For reference, the controller 1100 may further include a buffer memory (not illustrated) for storing data. Here, the buffer memory may be used to store data that is transferred to an external device through the host interface 1130 or data that is transferred from the memory device 1200 through the memory interface 1150. The controller 1100 may further include a ROM which stores code data to interface with the host.

Because the memory system 1000 according to an embodiment of the present disclosure includes the memory device 1200 having improved integration and enhanced characteristics, the integration and characteristics of the memory system 1000 may also be improved.

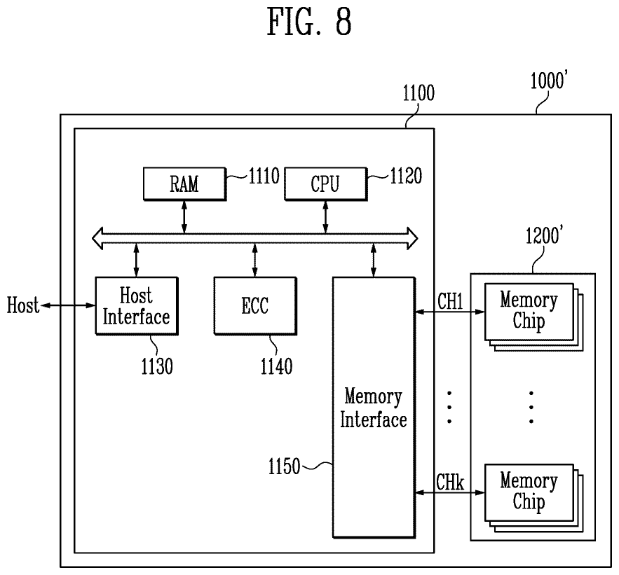

FIG. 8 is a block diagram illustrating the configuration of a memory system according to an embodiment of the present disclosure. Hereinafter, repetitive description of configurations identical to those described above will be omitted.

Referring to FIG. 8, a memory system 1000′ according to an embodiment of the present disclosure may include a memory device 1200′ and a controller 1100. Also, the controller 1100 may include a RAM 1110, a CPU 1120, a host interface 1130, an ECC circuit 1140, a memory interface 1150, etc.

The memory device 1200′ may be a nonvolatile memory, and may be a semiconductor device, described above with reference to FIG. 1 to 3, or 5, and may be manufactured according to the manufacturing methods, described above with reference to FIGS. 4A to 41 or FIGS. 6A to 6J. Because the structure of the memory device 1200′ and the manufacturing methods thereof are the same as those described above, detailed description thereof will be omitted.

Further, the memory device 1200′ may be a multi-chip package including a plurality of memory chips. The plurality of memory chips may be divided into a plurality of groups. The plurality of groups may communicate with the controller 1100 through first to k-th channels CH1 to CHk. Also, the memory chips of each group may communicate with the controller 1100 through a common channel. For reference, the memory system 1000′ may be modified such that each single memory chip is coupled to a corresponding single channel.

As described above, because the memory system 1000′ according to an embodiment of the present disclosure includes the memory device 1200′ having improved integration and enhanced characteristics, the integration and characteristics of the memory system 1000′ may also be improved. In particular, the memory device 1200′ in an embodiment may be formed of a multi-chip package, whereby the data storage capacity of the memory system 1000′ may be increased, and the operating speed thereof can be enhanced.

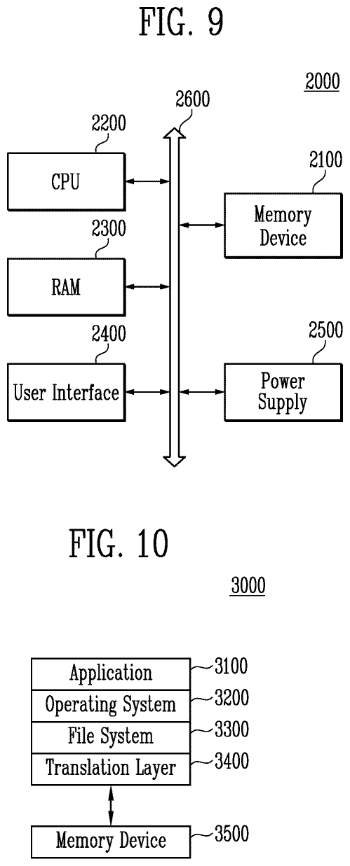

FIG. 9 is a block diagram illustrating the configuration of a computing system according to an embodiment of the present disclosure. Hereinafter, repetitive description of configurations identical to those described above will be omitted.

Referring to FIG. 9, a computing system 2000 according to an embodiment of the present disclosure may include a memory device 2100, a CPU 2200, a RAM 2300, a user interface 2400, a power supply 2500, a system bus 2600, etc.

The memory device 2100 stores data provided through the user interface 2400, data processed by the CPU 2200, etc. Further, the memory device 2100 may be electrically connected to the CPU 2200, the RAM 2300, the user interface 2400, the power supply 2500, etc. through the system bus 2600. For example, the memory device 2100 may be connected to the system bus 2600 through a controller (not illustrated) or, alternatively, directly connected to the system bus 2600. In the case where the memory device 2100 is directly connected to the system bus 2600, the function of the controller may be performed by the CPU 2200, the RAM 2300, etc.

Here, the memory device 2100 may be a nonvolatile memory, and may be a semiconductor device, described above with reference to FIG. 1 to 3, or 5, and may be manufactured according to the manufacturing methods, described above with reference to FIGS. 4A to 4I or FIGS. 6A to 6J. Because the structure of the memory device 2100 and the manufacturing methods thereof are the same as those described above, detailed description thereof will be omitted.

Further, as described above with reference to FIG. 8, the memory device 2100 may be a multi-chip package including a plurality of memory chips.

The computing system 2000 having the above-described configuration may be provided as one of various elements of an electronic device such as a computer, a ultra-mobile PC (UMPC), a workstation, a net-book, a personal digital assistants (PDA), a portable computer, a web tablet, a wireless phone, a mobile phone, a smartphone, an e-book, a portable multimedia player (PMP), a game console, a navigation device, a black box, a digital camera, a 3-dimensional (3D) television, a digital audio recorder, a digital audio player, a digital picture recorder, a digital picture player, a digital video recorder, a digital video player, a device capable of transmitting/receiving information in an wireless environment, one of various devices constituting a home network, one of various electronic devices constituting a computer network, one of various electronic devices constituting a telematics network, an RFID device, or the like.

As described above, because the computing system 2000 according to an embodiment of the present disclosure includes the memory device 2100 having improved integration and enhanced characteristics, the characteristics of the computing system 2000 may also be improved.

FIG. 10 is a block diagram illustrating a computing system according to an embodiment of the present disclosure.

Referring to FIG. 10, a computing system 3000 according to an embodiment of the present disclosure may include a software layer which includes an operating system 3200, an application 3100, a file system 3300, a translation layer 3400, etc. Further, the computing system 3000 may include a hardware layer such as a memory device 3500.

The operating system 3200 may manage software resources, hardware resources, etc. of the computing system 3000, and may control program execution by the CPU. The application 3100 may be any of various applications to be executed in the computing system 3000, and may be a utility executed by the operating system 3200.

The file system 3300 may refer to a logical structure for controlling data, files, etc. which are present in the computing system 3000, and may organize files or data to be stored in the memory device 3500 or the like based on certain rules. The file system 3300 may be determined depending on the operating system 3200 used in the computing system 3000. For example, when the operating system 3200 is Microsoft's Windows series, the file system 3300 may be a file allocation table (FAT), an NT file system (NTFS), or the like. Also, when the operating system 3200 is the Unix/Linux family, the file system 3300 may be an extended file system (EXT), a Unix file system (UFS), a journaling file system (JFS), or the like.

Although the operating system 3200, the application 3100 and the file system 3300 are illustrated as separate blocks in the drawing, the application 3100 and the file system 3300 may be included in the operating system 3200.

The translation layer 3400 translates an address into a form suitable for the memory device 3500 in response to a request from the file system 3300. For example, the translation layer 3400 may translate a logical address generated by the file system 3300 into a physical address of the memory device 3500. Here, mapping information of the logical address and physical address may be stored in an address translation table. For example, the translation layer 3400 may be a flash translation layer (FTL), a universal flash storage link layer (ULL), or the like.

The memory device 3500 may be a nonvolatile memory, and may be a semiconductor device, described above with reference to FIG. 1 to 3, or 5, and may be manufactured according to the manufacturing methods, described above with reference to FIGS. 4A to 4I or FIGS. 6A to 6J. Because the structure of the memory device 3500 and the manufacturing methods thereof are the same as those described above, detailed description thereof will be omitted.

The computing system 3000 having the above-mentioned configuration may be divided into an operating system layer implemented in a higher-level area and a controller layer implemented in a lower-level area. The application 3100, the operating system 3200, and the file system 3300 may be included in the operating system layer, and may be driven by a working memory of the computing system 3000. Also, the translation layer 3400 may be included in the operating system layer or the controller layer.

As described above, because the computing system 3000 according to an embodiment of the present disclosure includes the memory device 3500 having improved integration and enhanced characteristics, the characteristics of the computing system 3000 may also be improved.

According to an embodiment of the present disclosure, pads connected to contact plugs, respectively, are extended to have different lengths in a horizontal direction and are connected to lower contacts through extenders. In an embodiment, this can improve the positional constraints of lower lines connected to the lower contacts.

What is claimed is:

1. A semiconductor device, comprising:
a source layer spaced apart from a substrate and disposed in a cell area of the substrate;
a source cutting insulating layer spaced apart from the substrate and disposed in a contact area of the substrate;
a plurality of discharge contacts penetrating the source cutting insulating layer and extending downwards towards the substrate; and
a plurality of contact pads penetrating the source cutting insulating layer and contacting upper portions of the plurality of discharge contacts, respectively,
wherein each of the plurality of contact pads comprises an extender extending in a horizontal direction.

2. The semiconductor device according to claim 1,
wherein the plurality of contact pads are arranged in a first horizontal direction, and
wherein the extender of each of the plurality of contact pads extends in a second horizontal direction substantially orthogonal to the first horizontal direction.

3. The semiconductor device according to claim 1, wherein the extenders of the plurality of contact pads extend to different lengths.

4. The semiconductor device according to claim 1, wherein lower surfaces of ends of the extenders extended from the plurality of contact pads and contact upper surfaces of the plurality of discharge contacts, respectively.

5. The semiconductor device according to claim 1, further comprising:
a plurality of lower lines contacting lower surfaces of the plurality of discharge contacts, respectively,
wherein the plurality of lower lines are arranged substantially parallel to each other, and
wherein a portion of the plurality of lower lines extends in a first direction, while a remainder of the plurality of lower lines extends in a second direction opposite to the first direction.

6. The semiconductor device according to claim 1, wherein the source layer and the source cutting insulating layer are disposed adjacent to each other substantially on an identical level.

7. The semiconductor device according to claim 1, further comprising:
a cell stacked layer including interlayer insulating layers and conductive patterns that are alternately stacked on the source layer; and
a dummy stacked body including dummy interlayer insulating layers and sacrificial insulating layers that are alternately stacked on the source cutting insulating layer.

8. The semiconductor device according to claim 7, further comprising:
a channel structure penetrating the cell stacked layer and extending into the source layer.

9. The semiconductor device according to claim 7, further comprising:
a plurality of contact plugs extending in a vertical direction within the dummy stacked body and contacting upper surfaces of the contact pads.

10. A semiconductor device, comprising:
a source layer spaced apart from a substrate and disposed in a cell area of the substrate;
a source cutting insulating layer spaced apart from the substrate and disposed in a contact area of the substrate;
a cell stacked layer including interlayer insulating layers and conductive patterns that are alternately stacked on the source layer;
a dummy stacked body including dummy interlayer insulating layers and sacrificial insulating layers that are alternately stacked on the source cutting insulating layer;
a channel structure penetrating the cell stacked layer and extending into the source layer;
a cell plug pad disposed between the source layer and the channel structure;
a plurality of discharge contacts penetrating the source cutting insulating layer and extending downwards towards the substrate; and
a plurality of contact pads penetrating the source cutting insulating layer and contacting upper portions of the plurality of discharge contacts, respectively,
wherein each of the plurality of contact pads comprises an extender extending in a horizontal direction.

11. The semiconductor device according to claim 10,
wherein the plurality of contact pads are arranged in a first horizontal direction, and
wherein the extender of each of the plurality of contact pads extends in a second horizontal direction substantially orthogonal to the first horizontal direction.

12. The semiconductor device according to claim 10, wherein the extenders of the plurality of contact pads extend to different lengths.

13. The semiconductor device according to claim 10, wherein lower surfaces of ends of the extenders extended from the plurality of contact pads and contact upper surfaces of the plurality of discharge contacts, respectively.

14. The semiconductor device according to claim 10, further comprising:
a plurality of lower lines contacting lower surfaces of the plurality of discharge contacts, respectively,
wherein the plurality of lower lines are arranged substantially parallel to each other, and
wherein a portion of the plurality of lower lines extends in a first direction, while a remainder of the plurality of lower lines extends in a second direction opposite to the first direction.

15. The semiconductor device according to claim 10, wherein the source layer and the source cutting insulating layer are disposed adjacent to each other substantially on an identical level.

16. A method of manufacturing a semiconductor device, comprising:
forming a source layer on a memory cell area of a substrate, and forming a source cutting insulating layer on a contact area of the substrate;
forming openings that pass through the source cutting insulating layer, and forming discharge contacts by filling the openings with a conductive material;
forming recess areas each including extenders that overlap the discharge contacts; and
forming contact pads within the recess areas.

17. The method according to claim 16, wherein the contact pads are arranged side by side in a first horizontal direction, and each of the contact pads is formed to include an extender extending in a second horizontal direction substantially orthogonal to the first horizontal direction.

18. The method according to claim 17, wherein the extender of each of the contact pads is connected to any one of the discharge contacts.

19. The method according to claim 16, wherein forming the source layer comprises:
sequentially stacking a first semiconductor layer, a first protective layer, a sacrificial layer, a second protective layer, and a second semiconductor layer on the substrate.

20. The method according to claim 19, wherein, in forming the recess areas, a plurality of holes are formed to pass through the second semiconductor layer, the second protective layer, the sacrificial layer, and the first protective layer and extend into the first semiconductor layer.

21. The method according to claim 20, wherein, in forming the contact pads, the plurality of holes are filled with a conductive material to form sacrificial patterns.

22. The method according to claim 21, further comprising:
forming a stacked body in which a first material layer and a second material layer are alternately stacked on a structure including the source layer and the source cutting insulating layer, after forming the contact pads and the sacrificial patterns; and
forming a plurality of channel holes that pass through the stacked body to expose the sacrificial patterns.

23. The method according to claim 22, further comprising:
extending the channel holes by removing the sacrificial patterns;
forming a channel structure by sequentially stacking a memory layer and a channel semiconductor layer along sidewalls of the channel holes;
forming a slit that passes through the stacked body, the second semiconductor layer, and the second protective layer to expose the second semiconductor layer;
exposing a portion of a sidewall of the memory layer by removing the second semiconductor layer exposed through the slit;
exposing a portion of a sidewall of the channel semiconductor layer by etching the exposed portion of the sidewall of the memory layer; and
forming a third semiconductor layer that contacts the exposed portion of the sidewall of the channel semiconductor layer in a space where the second semiconductor layer is removed by introducing a conductive material through the slit.

24. A method of manufacturing a semiconductor device comprising:
forming a source layer on a memory cell area of a substrate, and forming a source cutting insulating layer on a contact area of the substrate;
forming openings that pass through the source cutting insulating layer, and forming discharge contacts by filling the openings with a conductive material;
forming recess areas each including extenders that overlap the discharge contacts;
forming a plurality of holes by etching the source layer to a certain depth; and
forming contact pads in the recess areas, and forming cell plug pads in the plurality of holes.

25. The method according to claim 24, wherein the contact pads are arranged side by side in a first horizontal direction, and each of the contact pads is formed to include an extender extending in a second horizontal direction substantially orthogonal to the first horizontal direction.

26. The method according to claim 25, wherein the extender of each of the contact pads is connected to any one of the discharge contacts.

27. The method according to claim 24, wherein forming the source layer sequentially stacks a first semiconductor layer, a first protective layer, a sacrificial layer, a second protective layer, and a second semiconductor layer on the substrate.

28. The method according to claim 27, wherein the plurality of holes are formed by etching the second semiconductor layer to expose the second protective layer.

29. The method according to claim 28, further comprising:
forming a stacked body in which a first material layer and a second material layer are alternately stacked on an entire structure including the source layer and the source cutting insulating layer, after forming the contact pads and the cell plug pads; and
forming a plurality of channel holes that pass through the stacked body and the cell plug pads to expose the second protective layer.

30. The method according to claim 29, further comprising:
forming a channel structure by sequentially stacking a memory layer and a channel semiconductor layer along sidewalls of the channel holes;
forming a slit that passes through the stacked body, the second semiconductor layer, and the second protective layer to expose the second semiconductor layer;
exposing the first protective layer and the second protective layer by removing the second semiconductor layer exposed through the slit;
exposing the channel semiconductor layer on a bottom surface of the channel structure by removing the first protective layer and the second protective layer and etching the exposed memory layer; and
forming a third semiconductor layer that contacts the exposed surface of the channel semiconductor layer in a space where the second semiconductor layer is removed by introducing a conductive material through the slit.
